(19) United States
(12) Patent Application Publication
(10) Pub. No.: US 2026/0352082 A1
(43) Pub. Date: Nov. 5, 2026

(54) AVERAGE AND PEAK CURRENT SENSE SYSTEMS AND METHODS

(71) Applicant: pSemi Corporation, San Diego, CA (US)

(72) Inventors: Tim Wen Hui Yu, Fremont, CA (US); Gregory Szczeszynski, Nashua, NH (US)

(21) Appl. No.: 19/736,704

(22) Filed: Jul. 9, 2026

Related U.S. Application Data
(63) Continuation of application No. PCT/US2025/011236, filed on Jan. 10, 2025.
(60) Provisional application No. 63/620,763, filed on Jan. 12, 2024.

(51) Int. Cl. H02M 1/00; G01R 19/00; G01R 19/04; G01R 19/165; H02M 1/14; H02M 1/32; H02M 3/07

(52) U.S. Cl. CPC H02M 1/0009; G01R 19/003; G01R 19/04; G01R 19/16538; H02M 1/14; H02M 1/325; H02M 3/07

(57) ABSTRACT

Circuits and methods are provided that use a comparator circuit within a multi-level converter to identify a signal that controls access to a loop circuit. A loop circuit receives multiple signals requesting multiple currents from the loop circuit. A comparator within the loop circuit determines a control signal indicating one of the multiple signals that controls the loop circuit, where the one of the signals that controls the loop circuit is associated with a lowest current from multiple currents.

### CROSS-REFERENCE TO RELATED APPLICATIONS

This patent application is a continuation of International Patent Application No. PCT/US2025/011236 filed Jan. 10, 2025 and entitled “AVERAGE AND PEAK CURRENT SENSE SYSTEMS AND METHODS” which claims the benefit of and priority to U.S. Provisional Patent Application No. 63/620,763 filed Jan. 12, 2024 and entitled “AVERAGE AND PEAK CURRENT SENSE SYSTEMS AND METHODS,” which are incorporated herein by reference in their entirety.

This patent application and International Patent Application No. PCT/US2025/011236 filed Jan. 10, 2025 and entitled “AVERAGE AND PEAK CURRENT SENSE SYSTEMS AND METHODS” are related to the following United States Provisional Patent Applications filed on Jan. 12, 2024, which are all incorporated herein by reference in their entirety:
Application No. 63/620,507 entitled “LEVEL SHIFTER AND BOOT CAPACITOR CIRCUITS, SYSTEMS, AND METHODS;”
Application No. 63/620,623 entitled “LEVEL SHIFTER AND BOOT CAPACITOR CIRCUITS, SYSTEMS, AND METHODS;”
Application No. 63/620,613 entitled “INTEGRATED CURRENT RESISTOR SENSING FOR MULTI-LEVEL CONVERTER;”
Application No. 63/620,465 entitled “STARTUP INTERLOCK FOR POWER CONVERTER CIRCUITS;”
Application No. 63/620,331 entitled “FULLY DIFFERENTIAL LEVEL SHIFT IN A NOISY ENVIRONMENT;”
Application No. 63/620,450 entitled “CAPACITOR SENSING AND CAPACITOR BALANCING SYSTEMS AND METHODS;”
Application No. 63/620,469 entitled “CAPACITOR SENSING AND CAPACITOR BALANCING SYSTEMS AND METHODS;”
Application No. 63/620,678 entitled “RECONFIGURABLE MULTI-LEVEL POWER CONVERTER TO CHARGE PUMP MODE AND FRACTIONAL CHARGE PUMP MODE;”
Application No. 63/620,417 entitled “INPUT CURRENT SLEW FOR A MULTI-LEVEL CONVERTER;”
Application No. 63/620,726 entitled “ADJUSTING OVERVOLTAGE PROTECTION BASED ON MODE OF OPERATION SYSTEMS AND METHODS;”
Application No. 63/620,737 entitled “HYBRID PEAK AVERAGE CURRENT MODE CONTROL;”
Application No. 63/620,741 entitled “CURRENT LIMITED VOLTAGE MODE CONTROL OF MULTIPLE INPUTS;”
Application No. 63/620,527 entitled “MULTI-FUNCTION COMP PIN SYSTEMS AND METHODS;”
Application No. 63/620,488 entitled “LEVEL SHIFTER AND BOOT CAPACITOR CIRCUITS, SYSTEMS, AND METHODS;”
Application No. 63/620,553 entitled “MULTI-LEVEL REVERSE CURRENT BLOCKING SYSTEMS AND METHODS;”
Application No. 63/620,638 entitled “GENERAL STARTUP FOR MULTI-LEVEL POWER CONVERTER CIRCUITS;”
Application No. 63/620,733 entitled “PRECISION ANALOG TO DIGITAL CIRCUIT TUNED VOLTAGE AND CURRENT MODE DC-DC CONVERTER;”
Application No. 63/620,738 entitled “PREDICTIVE CONTROL LOOP PRE-CHARGING DURING A MULTI-LEVEL ZONE CHANGE;”
Application No. 63/620,764 entitled “DETECTOR CIRCUIT FOR DETECTING ONE OF MULTI-INPUT CONTROLLING SIGNALS THAT CONTROLS A CONTROL LOOP CIRCUIT;”
Application No. 63/620,607 entitled “STARTUP VOLTAGE SELECTION FOR MULTI-LEVEL POWER CONVERTER CIRCUITS;”
Application No. 63/620,575 entitled “MULTI-LEVEL CAPACITOR FAULT DETECTION SYSTEMS AND METHODS;”
Application No. 63/620,582 entitled “PARELLEL OPERATION OF MULTI-LEVEL POWER CONVERTERS;” and
Application No. 63/620,763 entitled “AVERAGE AND PEAK CURRENT SENSE SYSTEMS AND METHODS.”

### BACKGROUND

This disclosure relates to electronic circuits, and more particularly for example to multi-level power converters.

Many electronic products, including mobile computing and/or communication products and components (e.g., notebook computers, ultra-book computers, tablet devices, LCD, LED displays, and the like) use multiple voltage levels for operation. For example, radio frequency (RF) transmitter power amplifiers may operate at relatively high voltages (e.g., 12V or more), whereas logic circuitry may operate at a relatively low voltage level (e.g., 1-3V) and other circuitry may operate at an intermediate voltage level (e.g., 5-10V).

Direct current power converters are often used to generate a lower or higher voltage from a common power source, such as a battery, solar cells, and rectified AC sources. Power converters which generate a lower output voltage level from a higher input voltage power source are commonly known as buck converters, so-called because the output voltage V_{OUT} is less than the input voltage VIN, and hence the converter is “bucking” the input voltage. Power converters which generate a higher output voltage level from a lower input voltage power source are commonly known as boost converters, because V_{OUT} is greater than V_{IN}. Some power converters may be either a buck converter or a boost converter depending on which terminals are used for input and output. Some power converters may provide an inverted output.

One type of direct current power converter known as a multi-level power converter includes charge transfer capacitors as energy storage elements coupled by controlled switches to transfer charge from V_{IN} to V_{OUT}. Such charge transfer capacitors are commonly known as “fly capacitors” or “pump capacitors”. When a fly capacitor is used (i.e., not bypassed), the electrical energy flowing through that fly capacitor generally will either charge it or discharge it.

There is a continued need for improved circuits and methods for more effectively and efficiently operating and implementing various type of electrical circuits and devices, including for example multi-level converter circuits.

### SUMMARY

Embodiments of the present disclosure include systems, circuits, and methods for operating and implementing various electronics circuits, including multi-level converter circuits.

The embodiments are directed to a system comprising, a first circuitry configured to create a first differential current based on a first voltage across a first switch of a power converter when the first switch is in an on state, a second circuitry configured to create a second differential current based on a second voltage across a second switch of the power converter when the second switch is in the on state, a first pair of resistors configured to create a first differential voltage from the first differential current and a second differential voltage from the second differential current, a pilot device configured to create a pilot voltage based on the first differential voltage and the second differential voltage, and a pilot current from the pilot voltage, a third circuitry configured to pass the pilot current to a second pair of resistors, and a low pass filter configured to measure a current at the second pair of resistors and generate an average current of the power converter.

The embodiments are directed to a system comprising a first mirror circuitry configured to create a first differential current based on a first voltage across a first switch of a power converter when the first switch is in an on state, a second mirror circuitry configured to create a second differential current based on a second voltage across a second switch of the power converter when the second switch is in the on state, a first pair of resistors configured to create a first differential voltage from the first differential current and a second differential voltage from the second differential current, a pilot device configured to create a pilot current based on the first differential voltage and the second differential voltage, a third circuitry configured to pass the pilot current to a second pair of resistors, and determine a peak current at the second pair of resistors.

The embodiments are directed to a method creating, at a first mirror circuitry, a first differential current based on a first voltage across a first switch of a power converter when the first switch is on, creating, at a second mirror circuitry, a second differential current based on a second voltage across a second switch of the power converter when the second switch is on, generating a first differential voltage from the first differential current and a second differential voltage from the second differential current, converting, at a pilot device, the first differential voltage and the second differential voltage into a pilot current, passing the pilot current through a third circuitry to a pair of resistors and, measuring an average current of the power converter at the pair of resistors.

The scope of the present disclosure is defined by the claims, which are incorporated into this section by reference. A more complete understanding of embodiments of the present disclosure will be afforded to those skilled in the art, as well as a realization of additional advantages thereof, by a consideration of the following detailed description of one or more embodiments. Reference will be made to the appended sheets of drawings that will first be described briefly.

### DESCRIPTION OF THE DRAWINGS

FIG. 1A is an example power converter circuit with internal input current sense, in accordance with one or more embodiments of the present disclosure.

FIG. 1B is an example power converter circuit with external input current sense, in accordance with one or more embodiments of the present disclosure.

FIG. 2A is an example dual integrated circuit (IC) power converter circuit with internal input current sense, in accordance with one or more embodiments of the present disclosure.

FIG. 2B is an example dual IC power converter circuit with external input current sense, in accordance with one or more embodiments of the present disclosure.

FIG. 3A is an example functional block diagram of a power converter circuit, in accordance with one or more embodiments of the present disclosure.

FIG. 3B is an example functional block diagram of a power converter circuit, in accordance with one or more embodiments of the present disclosure.

FIG. 4 is a diagram illustrating an example charging function in step down regulation mode of an example power converter circuit, in accordance with one or more embodiments of the present disclosure.

FIG. 5 is a diagram illustrating an example charging function in step down divide by 3 charge pump mode, in accordance with one or more embodiments of the present disclosure.

FIG. 6 is a functional block diagram illustrating aspects of an example power converter circuit, in accordance with one or more embodiments of the present disclosure.

FIG. 7 is a block diagram illustrating an example system implementing a power converter circuit, in accordance with one or more embodiments of the present disclosure.

FIG. 8A is a circuit diagram illustrating an example 3-level converter circuit, in accordance with one or more embodiments of the present disclosure.

FIG. 8B is a circuit diagram illustrating an example 4-level converter circuit, in accordance with one or more embodiments of the present disclosure.

FIG. 8C is a circuit diagram illustrating an example M-level converter circuit, in accordance with one or more embodiments of the present disclosure.

FIG. 9 is an example M-level converter circuit, in accordance with one or more embodiments of the present disclosure.

FIG. 10 is a block diagram of an example embodiment of control circuitry for an M-level converter cell, in accordance with one or more embodiments of the present disclosure.

FIG. 11 is a block diagram of a controller, in accordance with one or more embodiments of the disclosure.

FIG. 12 is a diagram of an example average current across an inductor, in accordance with one or more embodiments of the disclosure.

FIGS. 13A-13C are circuit diagrams of a circuitry for determining an average current and peak current, in accordance with one or more embodiments of the disclosure.

FIG. 14 is a diagram of a voltage waveform created by the power converter, in accordance with one or more embodiments of the disclosure

FIG. 15 is a circuit diagram of a portion of circuit that includes blanking circuitry, in accordance with one or more embodiments of the disclosure.

FIG. 16 is an example method for measuring average current and peak current of a multi-level converter, in accordance with one or more embodiments.

Embodiments of the present disclosure and their advantages are best understood by referring to the detailed description that follows. It is noted that sizes of various components and distances between these components are not drawn to scale in the figures. It should be appreciated that like reference numerals are used to identify like elements illustrated in one or more of the figures.

### DETAILED DESCRIPTION

The present disclosure encompasses novel circuits, architectures, systems, and methods that more effectively and efficiently address the configuration and operation of multi-level converter circuits. It will be appreciated that various improvements disclosed herein encompass innovative circuits, hardware components, architectures, and related logic that are applicable to applications beyond multi-level converter circuits.

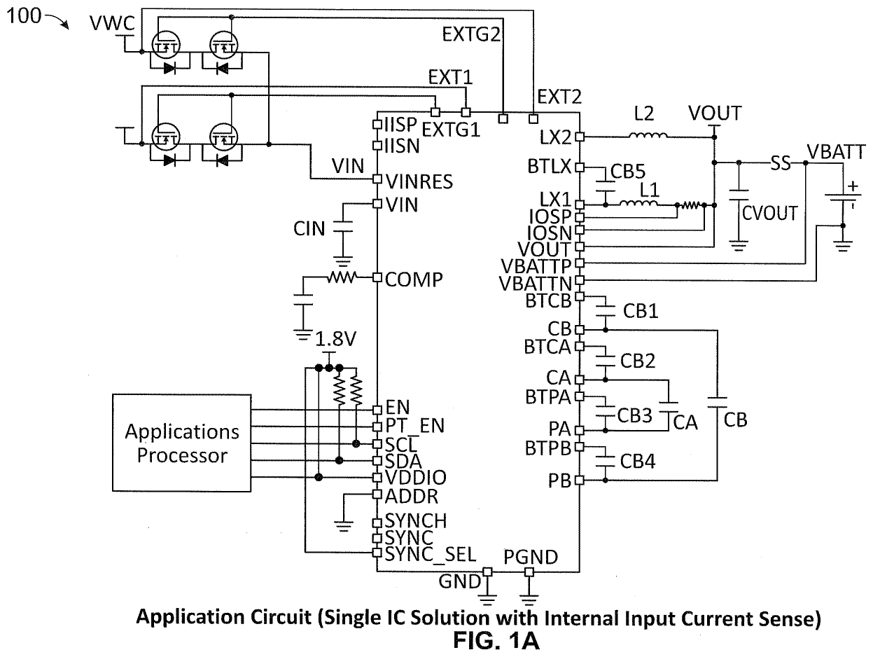

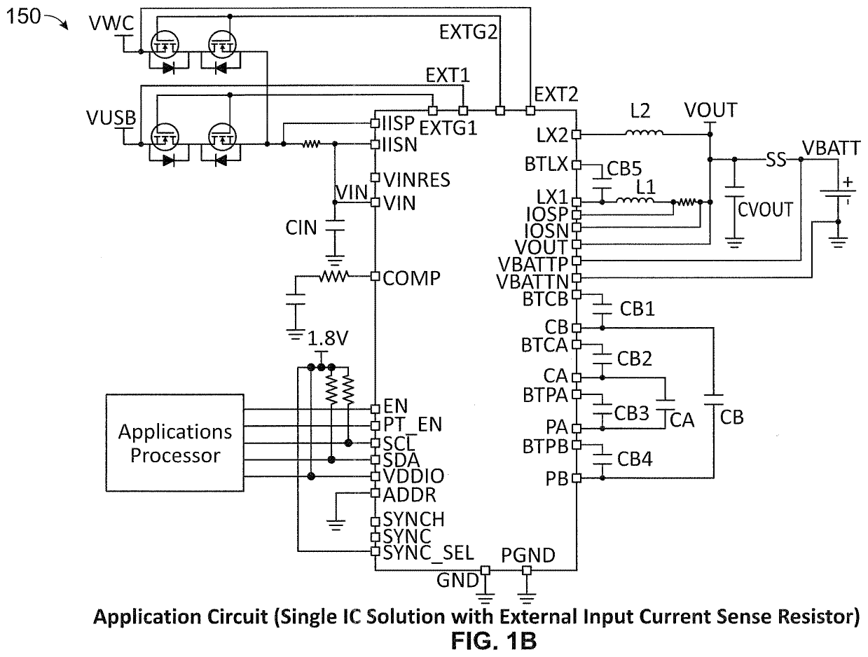

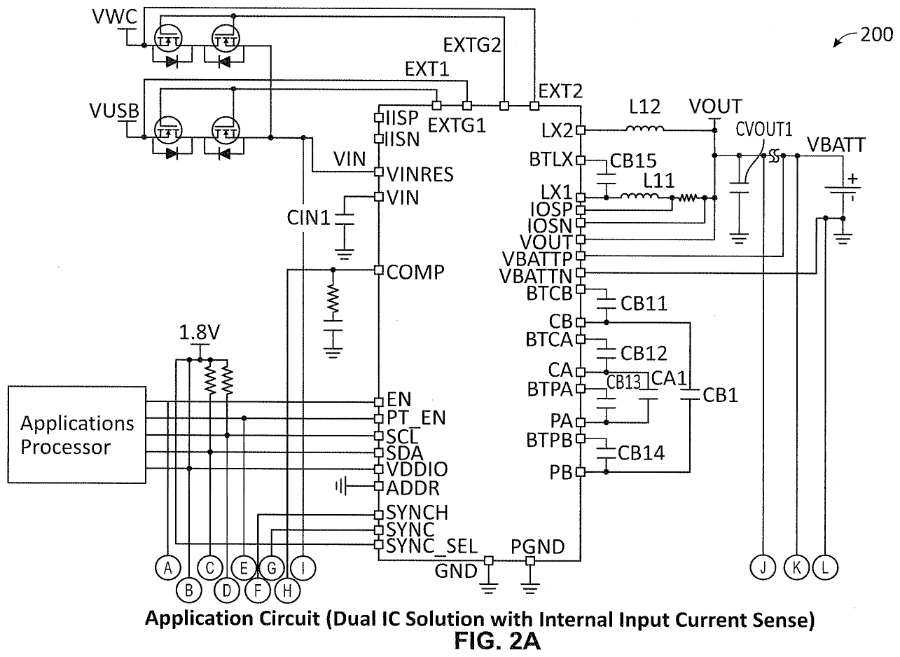

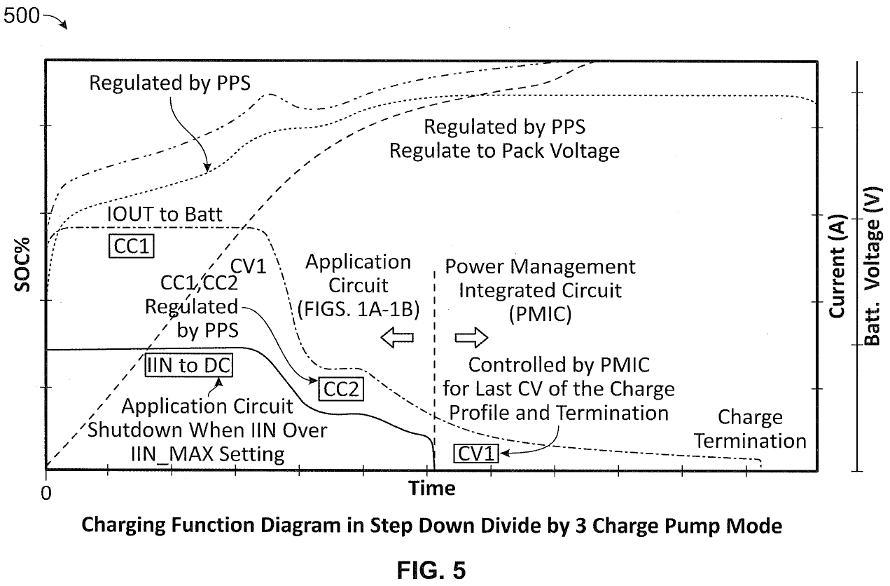

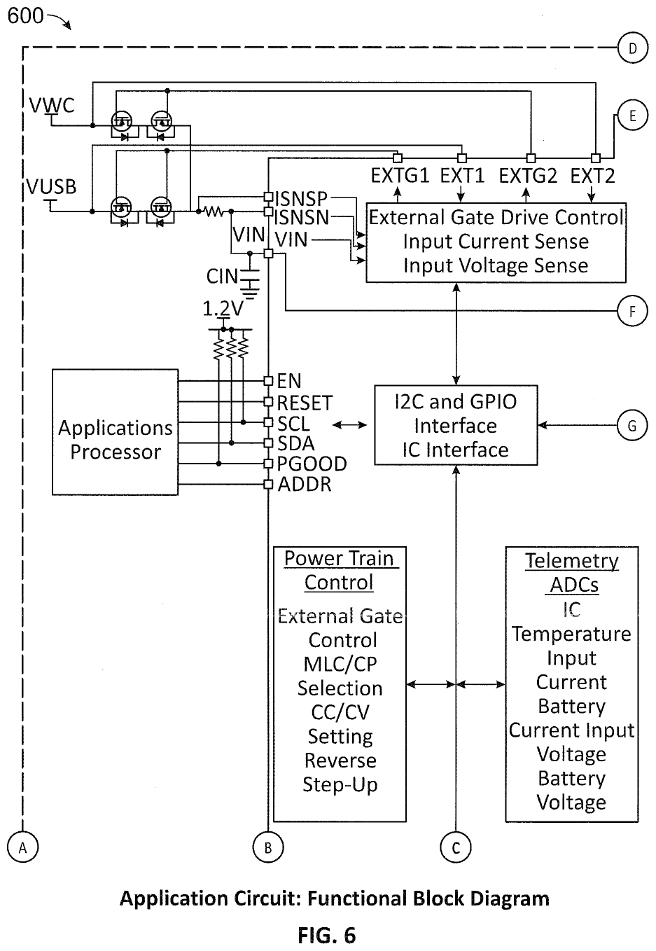

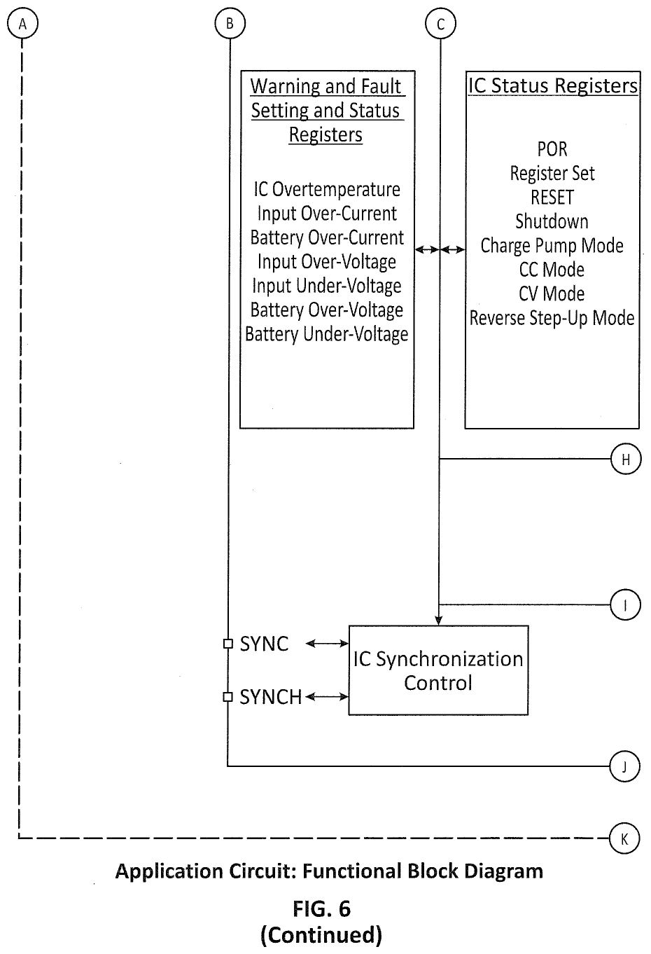

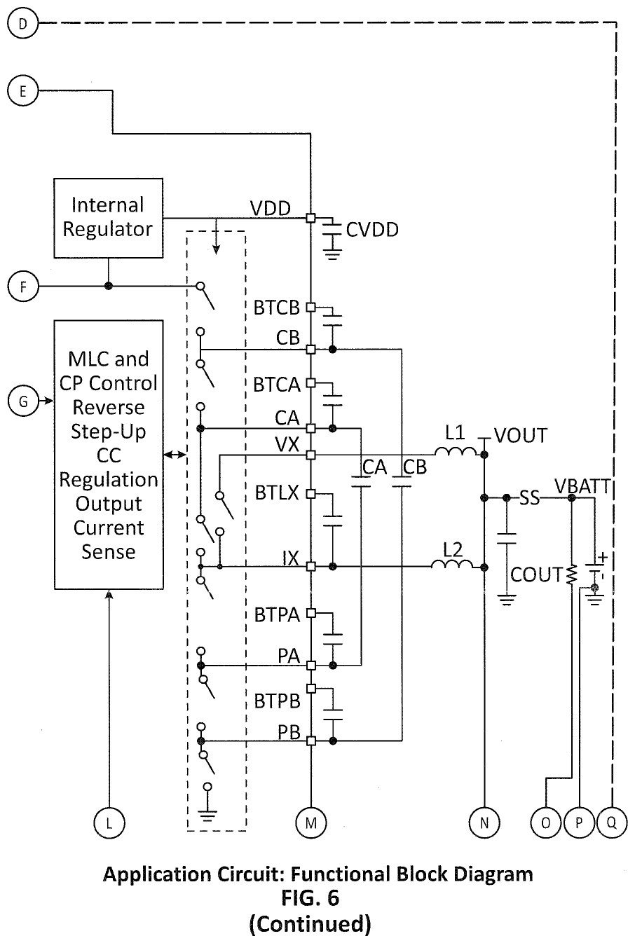

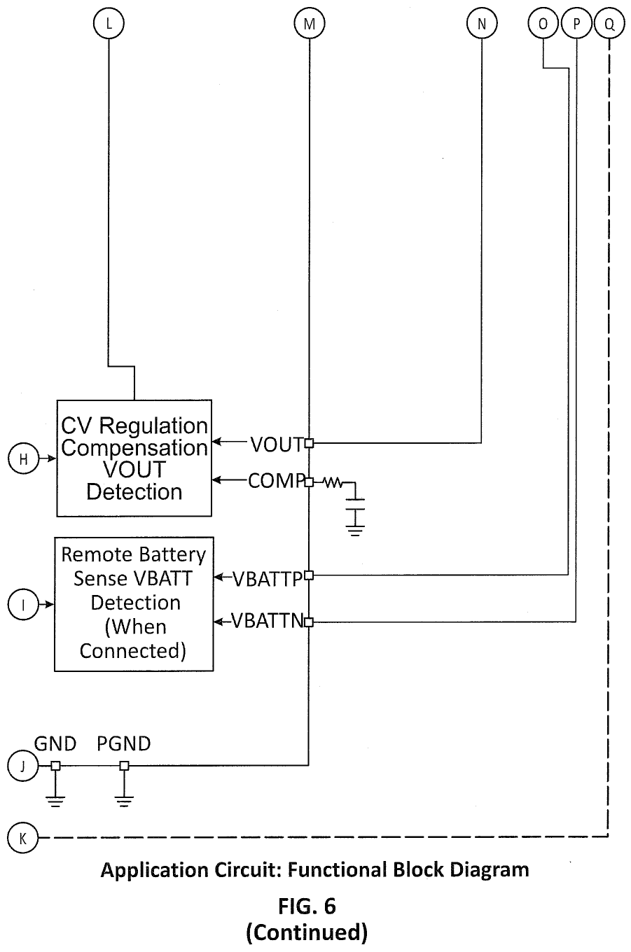

FIGS. 1-6 illustrate various embodiments of a high efficiency 4-level step-down and step-up power converter for battery charging applications, such as single cell Li-ion and Li-polymer battery applications. In the illustrated embodiments, the power converter is configured to deliver up to 5 amperes (A) of charging current in regulation mode and in a divide-by-3 charge pump mode, though other configurations are within the scope of the present disclosure. The power converter can be configured, for example, into dual ICs operation for 9 A charging current in regulation mode and in divide-by-3 charge pump mode. Although a 4-level power converter is illustrated, it will be appreciated that the embodiments described herein may be applicable to various M-level implementations, where M>=3.

In some implementations, for example, the power converter may supply an input range of approximately 4.5 V to 18 V input to support both universal serial bus (USB) and wireless inputs, and in a reverse step-up mode, the output may be programmable from 4.8 V to 16 V in 100 mV step with a programmable output current limit up to 1.7 A. This input voltage range may be used, for example, to support fast charging of single Li-Ion cells from USB and wireless input. It will be appreciated that other voltage and current ranges and limits may be implemented depending on the application. It will also be appreciated that while compatibility with USB is described herein, other wired interfaces and protocols may be implemented with the power converter of the present disclosure.

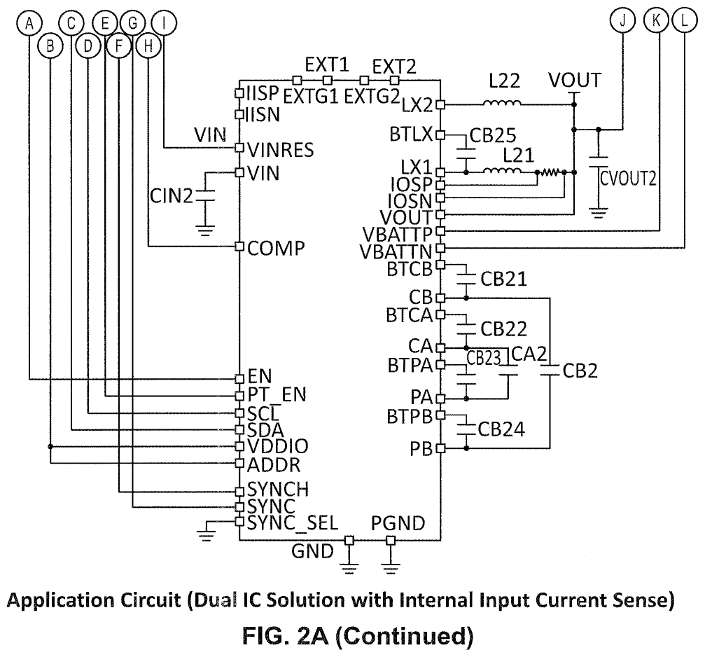

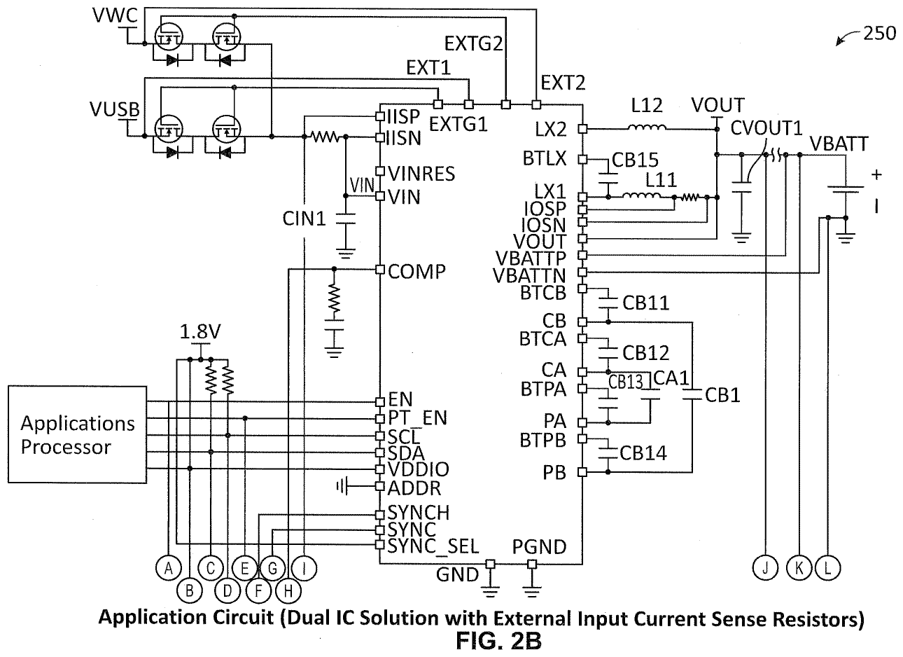

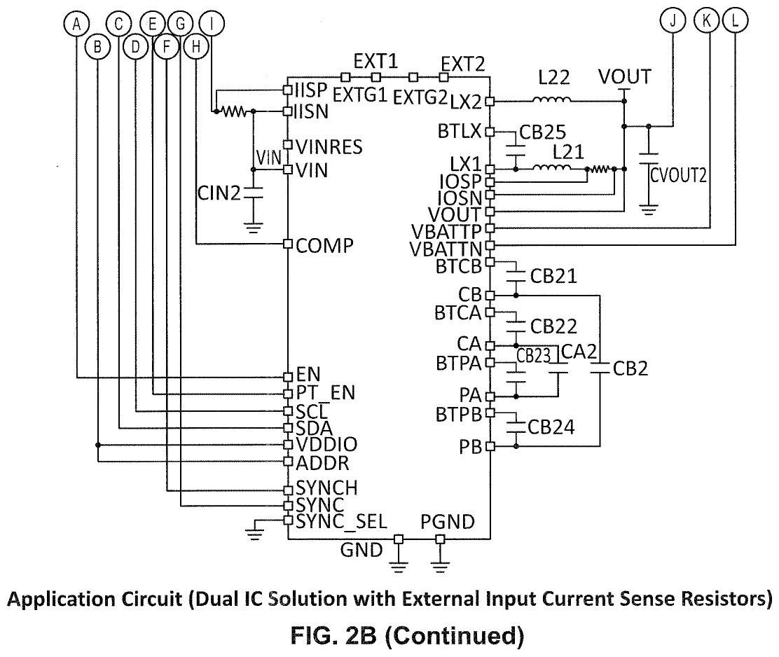

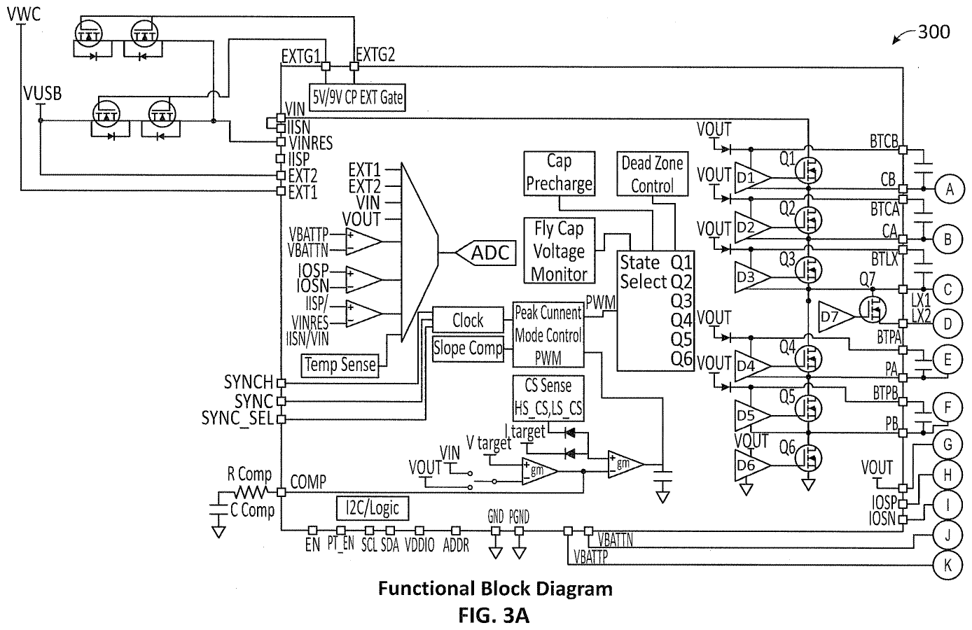

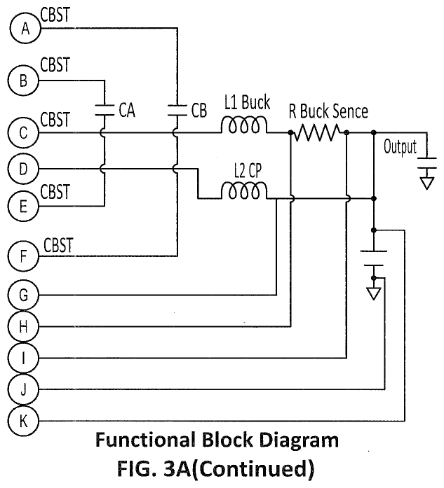

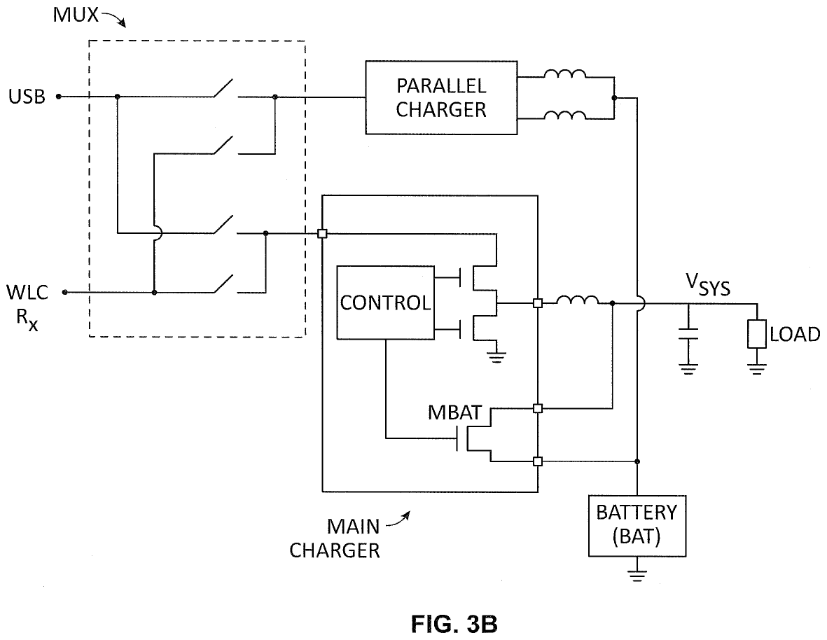

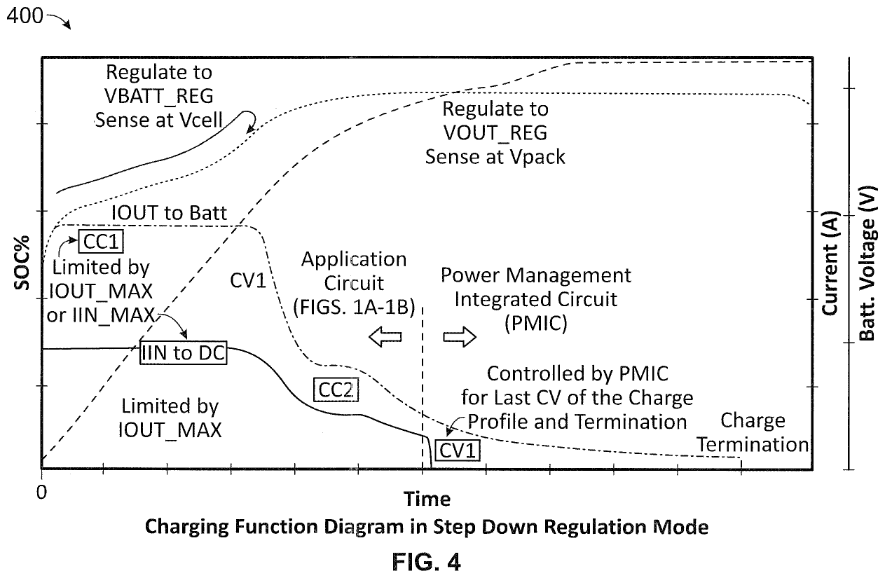

In various embodiments, the power converter may be implemented as a single integrated circuit (IC) (see, e.g., FIGS. 1A-B), dual-integrated circuits (see, e.g., FIGS. 2A-B), or in other configurations depending on the implementation. In various embodiments, the power converter may operate as a parallel charger along with a main charger, as shown in FIG. 3B, to provide the desired functionality noted herein and, for example, as illustrated in FIGS. 4 and 5 for the desired charging functionality for various applications, as would be understood by one skilled in the art. FIG. 3B may represent a system level point of view of a mobile architecture having a parallel charger and a main charger that accepts power from a wired port (e.g., a wired USB) or from a wireless interface. The parallel charger for one or more embodiments may represent an IC as illustrated in FIGS. 1-3A, for example, and may function to charge a battery for some portion of the charging profile (e.g., as shown in FIGS. 4 and 5), while the main charger charges the battery for other portions of the charging profile. In various embodiments, the parallel charger may also be configured to function as the main charger as well, depending upon the desired application. The novel architecture disclosed herein may be implemented to enable (i) improved efficiency (e.g., at 9 A charging current) in a low-profile solution; (ii) low electromagnetic interference (EMI) fixed-frequency operation under heavy load conditions; (iii) input and output current and voltage, IC temperature monitoring and telemetry via inter-integrated circuit (LC) technology; and/or (iv) full protection including input and output under voltage lockout (UVLO), input and output over voltage protection (OVP), input and output over current protection (OCP), and IC over-temperature with fault and warning status. In some implementations, the power converter supports divide-by-3, step-down and step-up regulating modes, dual external disconnect switch control, and/or paralleled operation.

In the illustrated embodiments, the power converter is implemented as a multi-level charge pump incorporating power switches and control circuitry. The power converter's internal bias may be provided by the system battery through a VOUT connection (e.g., pin). The charging input can be USB (or other wired input) or wireless input by an external FET register control. In some implementations, the power converter may be programmed to different operating modes, which may include a step-down regulation mode, a step-down divide-by-3 charge pump mode, and a reverse step-up mode.

In a step-down regulation mode, the power converter operates as a multi-level step-down regulator to support USB power delivery (USB-PD) (or other wired protocol) or fixed input charging. During a constant-current (CC) phase, the maximum charging current may be limited for example, by configuring registers. When the input current does not reach a predetermined maximum input setting, the charge current is set to a predetermined maximum output setting. If the input current reaches the input maximum setting, then the charge current throttles and maintains input current at the input maximum setting. This allows maximum charging current while ensuring that the charge current does not go above a battery maximum current rating and the input current does not trip adapter over-current protection.

During a constant-voltage (CV) phase, the CV regulation may be limited, for example, by configuring registers. In operation, a single-wire sense pin or other sensor is configured to sense the output voltage VOUT, which is compared to a predetermined value stored in a register, VOUT_REG. The voltage differential between the battery's positive terminal and negative terminal is sensed and compared to a predetermined value stored in a register, VBATT_REG. In some implementations, a single-wire sense pin or other sensor senses VBATTP (battery voltage at positive terminal) and a single-wire sense pin or other sensor senses VBATTN (battery volage at negative terminal). The CV regulates to the lower of the two settings. If the VOUT sensed voltage reaches VOUT_REG first, then CV is regulated to VOUT_REG. If the VBATTP sensed voltage reaches VBATT_REG first, then CV is regulated to VBATT_REG. This provides a fast battery top off while preventing voltage above safety limit.

In a step-down divide-by-3 charge pump mode (which may be selected, for example, by setting a corresponding register), the power converter is configured as a divide-by-3 step-down charge divider to support USB-Programmable Power Supply (USB-PPS) or other charging protocol or programmable input charging. In some embodiments, the power converter allows the USB-PPS adapter to control voltage and current and ignores conflicting settings (e.g., settings stored in registers for IOUT_MAX, VOUT_REG and VBATT_REG). In this mode, the power converter monitors an IIN_MAX setting, shuts down the power train (which includes switches to configure, enable and disable various modes of operation) and disconnects external FET when IIN current exceeds IIN_MAX setting. In the illustrated embodiment, the output current is up to 10 A in dual IC operation and 5 A in single IC operation.

In a reverse step-up mode (which may be selected, for example, by setting a corresponding register) the power converter is configured as a multi-level step-up regulator to power peripheral device(s) connected to USB (or other wired protocol or standard) or wireless input. The power converter draws power from the system battery and regulates VIN to the VOUT_REG programmable setting of 4.8V to 16V. The VIN output current limit may be set, for example, by an IIN_MAX register.

In some embodiments, to enable the IC, both an EN pin and an IC_EN bit are set to logic high (1). When either the EN pin or IC_EN bit is set to logic low (0), the IC is disabled. After the IC is enabled, the POR status bit sets to 1 to indicate the IC has a fresh power up.

In some embodiments, the power converter provides a gate driver to control two external N-channel MOSFETs and sense inputs to monitor source input voltage at each FET. The external FETs may be controlled by registers (e.g., 1-bit registers V_EXTG, EXTG_EN and EXTGX). The V_EXTG bit sets the gate drive voltage and can be set to 9V or 5V, in the illustrated embodiment. The EXTGX bits select which FET(s) to turn on. The EXTG_EN bit enables the gate driver to turn on the selected FET(s). In various embodiments, the external FET can be turned on or off independently from other IC operations except when the IC is disabled. The EXT_EN_IND status bit set to 1 when external FET is enabled. When a fault is detected and triggers a shutdown, the external FET may be turned off automatically. If EXT1 or EXT2 detects an OVP, then the respected FET would not turn on from the off mode.

In various embodiments, the power train is enabled after all the registers have been initialized and the target input external FET is turned on. Sufficient time based on capacitance on the power path may be configured between the external FET on time and the power train on time to minimize in-rush current. Next, both PT_EN pin and PT_EN bit are set to logic high (1) to turn on the power train. When either PT_EN pin or PT_EN pin is logic low, the power train is off. In dual IC operation, the slave IC power train may be configured to turn on first before the master IC. The COMP, SYNC and SYNCH pins from two ICs gate the power train and synchronize the operation. The SYNC_SEL pin sets the IC to master mode or slave mode. IC internal fault and programmable fault detection shuts down the power train operation when fault is detected.

In a reverse step-up mode (which may be selected, for example, by setting a corresponding register), the power converter is configured as a multi-level step-up regulator to power peripheral device(s) connected to USB (or other wired port) or wireless input. The power converter draws power from the system battery and regulates V_{IN} pin to a VOUT_REG programmable setting of 4.8V to 16V. The V_{IN} output current limit is set by IIN_MAX register.

To enable the IC, both the EN pin and IC_EN bit are set to logic high (1). When either EN pin or IC_EN bit is set to logic low (0), the IC is disabled. After the IC enables, the POR status bit sets to 1 to indicate the IC has a fresh power up. The power converter provides a gate driver to control two external N-channel MOSFETs and sense inputs to monitor source input voltage at each FET. The external FETs are controlled by register bits, such as V_EXTG, EXTG_EN and EXTGX. The V_EXTG bit sets the gate drive voltage and can be set to 9V or 5V, for example. The EXTGX bits select which FET(s) to turn on. The EXTG_EN bit enables the gate driver to turn on the selected FET(s). The external FET can be turned on or off independently from other IC operation except when the IC is disabled. The EXT_EN_IND status bit set to 1 when external FET is enabled.

When a fault is detected and triggers a shutdown, the external FET may be turned off automatically. If EXT1 or EXT2 detects an OVP, then the respective FET would not turn on from off mode. The power train is enabled after all the registers have been initialized and the target input external FET is turned on. Sufficient time based on capacitance on the power path should be given between external FET on time to power train on time to minimize in-rush current. Next, both PT_EN pin and PT_EN bit are set to logic high (1) to turn on the power train. When either PT_EN pin or PT_EN pin is logic low, the power train is off. In dual IC operation, the slave IC power train is turned on before the master IC. The COMP, SYNC and SYNCH pins from the two ICs gate the power train and synchronize the operation. SYNC_SEL pin sets the IC to master mode or slave mode. IC internal fault and programmable fault detection shuts down power train operation when a fault is detected.

In accordance with various embodiments, an example power converter initialization, an example power up sequence, and an example fault handling will now be described for the three different operating modes. In an example step-down regulation mode, the initialization and power up sequence uses EXT1 as an example. The same sequence may apply to EXT2 with the only change in EXTGX bit and related EXT2 register settings. First, pull EN to logic high and then set IC_EN bit=1 at 100 us (TBD) after EN is logic high to enable IC. IC startup from POR stage, POR bit reports 1 indicating fresh IC startup. Next, the POR bit is read to confirm the IC is enabled. The FREQUENCY register is then set to a desired setting. In dual IC operation, both ICs are set to the same frequency setting. The VOUT_REG register is set to the target regulation voltage on the VOUT sense pin in CV operation. The VBATT_REG register is set to the target regulation voltage on the VBATTP sense pin in CV operation. The IOUT_MAX register is set to the target maximum charger current in CC operation, and the IIN_MAX register is set to a value below the adapter current limit. Next, the FAULT and WARNING registers was set to a desired setting. Each Fault and Warning enables at a different time based on IC status and operating mode. The WATCHDOG register is then set to a desired setting.

The MODE register and other related registers are set for step-down regulation mode, including power train setup and enablement of an external FET, while checking for faults. In a dual IC operation, the external FETs are controlled by the master IC. If a fault (e.g., OVP event) is detected, then a shutdown register may be set to “1” to indicate a fault shutdown event and a sequence to enable the external FET after the shutdown fault is initiated. Next, the power train is enabled. In a dual IC operation, the slave IC power train is turned on before the master IC. After the power train is enabled, a bit may be set to indicate that the power train is ready and charging the battery. In some embodiments, a watchdog timer may be set to periodically check the IC status during charging operation.

If a fault event is detected, then the IC determines which faults events were triggered, such as the power train may be set to enable but it is off due to fault(s), an external FET is set to enable but the FET is off due to fault(s). The shutdown procedure may include resetting register values and repeating setup steps of enabling the power train, external FET, or other component that is disabled due to a fault.

An example step-down divide-by-3 power converter mode initialization and power up sequence will now be described. The initialization and power up sequence uses EXT1 as an example, but it will be appreciated that the same sequence applies to EXT2 with a change in EXTGX bit and related EXT2 register settings. The EN is pulled to logic high and then IC_EN bit=1 at 100 us (TBD) after EN is logic high to enable IC. The IC starts up from POR stage, POR bit reports 1 indicating fresh IC startup. The POR bit is read to confirm the IC is enabled. The FREQUENCY register is set to a desired setting. In dual IC operation, both ICs are set to the same frequency setting. The IIN_MAX register is set to a value below the adapter current limit. VOUT_REG, VBATT_REG and IOUT_MAX registers are not used in step-down divide-by-3 charge pump mode. Voltage and current regulation in step-down divide-by-3 charge pump mode may be controlled by the PPS adapter. The FAULT, WARNING, and WATCHDOG registers are set to desired settings. Each Fault and Warning enables at different time based on IC status and operating mode.

The MODE register and other registers are set for step-down divide-by-three mode, including power train setup and external FET setup, while checking for faults. If a fault (e.g., OVP event) is detected, then a shutdown register may be set to “1” to indicate a fault shutdown event and a sequence to enable the power train or external FET, as appropriate, after the shutdown fault is initiated. Next, the power train is enabled. After the power train is enabled, a bit may be set to indicate that the power train is ready and charging the battery. In some embodiments, a watchdog timer may be set to periodically check the IC status during charging operation. Voltage and current regulation in step-down divide-by-3 charge pump mode may be controlled by the PPS adapter.

If a fault event is detected, then the IC determines which faults events were triggered, such as the power train may be set to enable but it is off due to fault(s), or an external FET is set to enable but the FET is off due to fault(s). The shutdown procedure may include resetting register values and repeating setup steps of enabling the power train, external FET, or other component that is disabled due to a fault.

An example reverse step-up mode initialization and power up sequence will now be described. This initialization and power up sequence uses EXT2 as an example, but the same sequence applies to EXT1 with the change in EXTGX bit and related EXT1 register setting. The value EN is pulled to logic high and then IC_EN bit is set to 1 at 100 us (TBD) after EN is logic high to enable IC. The IC starts up from the POR stage, and the POR bit reports 1 indicating a fresh IC startup. The POR bit is read to confirm the IC is enabled. Next, the FREQUENCY register is set to a desired setting. In dual IC operation, both ICs are set to the same frequency setting. The VOUT_REG register is set to the target regulation voltage at VIN. Next, the IIN_MAX register is set to the target current limit. VBATT_REG and IOUT_MAX registers are not used in reverse step-up mode. FAULT, WARNING, and WATCHDOG registers are set to desired settings. Each Fault and Warning enables at a different time based on IC status and operating mode.

The MODE register and other registers are set for reverse step-up mode, including power train setup and external FET setup, while checking for faults. If a fault (e.g., OVP event) is detected, then a shutdown register may be set to “1” to indicate a fault shutdown event and a sequence to enable the power train or external FET, as appropriate, after the shutdown fault is initiated. Next, the power train is enabled. After the power train is enabled, a bit may be set to indicate that the power train is ready and charging the battery. In some embodiments, a watchdog timer may be set to periodically check the IC status during charging operation. Voltage and current regulation in step-down divide-by-3 charge pump mode may be controlled by the PPS adapter. In dual IC operation, the slave IC power train is turned on before the master IC and is controlled by the master IC.

If a fault event is detected, then the IC determines which faults events were triggered, such as the power train may be set to enable but it is off due to fault(s), or an external FET is set to enable but the FET is off due to fault(s). The shutdown procedure may include resetting register values and repeating setup steps of enabling the power train, external FET, or other component that is disabled due to a fault. The EXT2 or V_{IN} pins are not configured to detect OVP as it is set as the output in reverse step-up mode. But if EXT2 or V_{IN} pin detects an OVP event, then IC_STATUS1 and IC_STATUS2 would report the fault event.

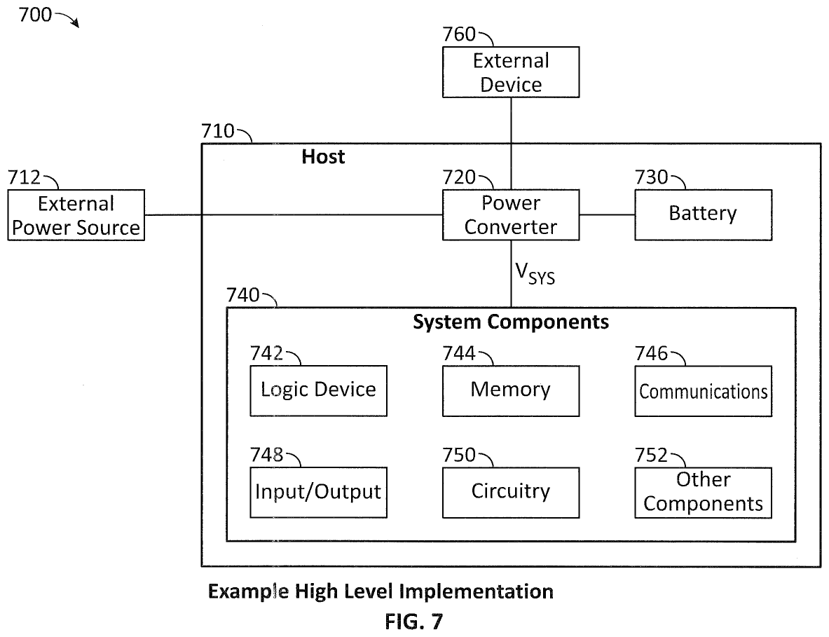

In an example system 700 illustrated in FIG. 7, a power converter 720 is implemented in a host 710 (e.g., a device or system) that includes a battery 730 and various system components 740. The host 710 may be any system or device that implements a power converter as described herein, including but not limited to a smart phone, tablet, portable electronics, a mobile device, low power electronics, and other electronic systems. The battery 730 may include one or more batteries that store electricity for use by the host 710, such as single cell Li-ion and Li-polymer batteries.

The power converter 720 may be configured to convert electricity stored in the battery 730 to a desired system voltage, V_{SYS}, for powering various system components 740, which may include one or more logic devices 742, memories 744, communications components 746, input/output (I/O) components 748, circuitry 750, and other components 752. The power converter 720 may also supply power to one or more external devices 760, such as a component connected to the host 710 through a wired or wireless connection, such as a USB compatible device. The power converter 720 may also be configured to receive power from an external power source 712 and convert the received power to the battery 730 for storage, or to the system components 740 and/or external device 760, as applicable.

In various embodiments, the one or more logic devices 742 and memories 744 may be configured to perform operations of the host 710. A logic device 742 may be implemented as a general-purpose processor, a digital signal processor (DSP), an application-specific integrated circuit (ASIC), a microcontroller, a programmable logic device (PLD), a field-programmable gate array (FPGA), or other programmable logic device(s). The logic device 742 and other components may be configured through hardwiring, software execution, or a combination of both. In various embodiments, the host 710 includes one or more memory devices designed to retain data, such as software instructions for execution by the logic device. The memory may include volatile and non-volatile memories, such as random-access memory (RAM), dynamic RAM (DRAM), static RAM (SRAM), non-volatile random-access memory (NVRAM), read-only memory (ROM), programmable read-only memory (PROM), erasable programmable read-only memory (EPROM), electrically-erasable programmable read-only memory (EEPROM), flash memory, hard disk drives, or other memory types. The logic device may be configured to execute software instructions residing in the memory, thereby accomplishing method steps and operations.

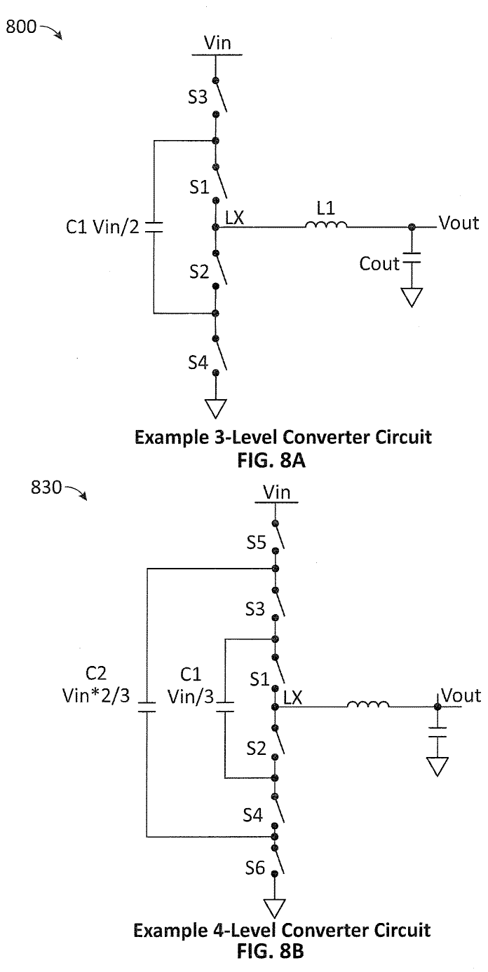

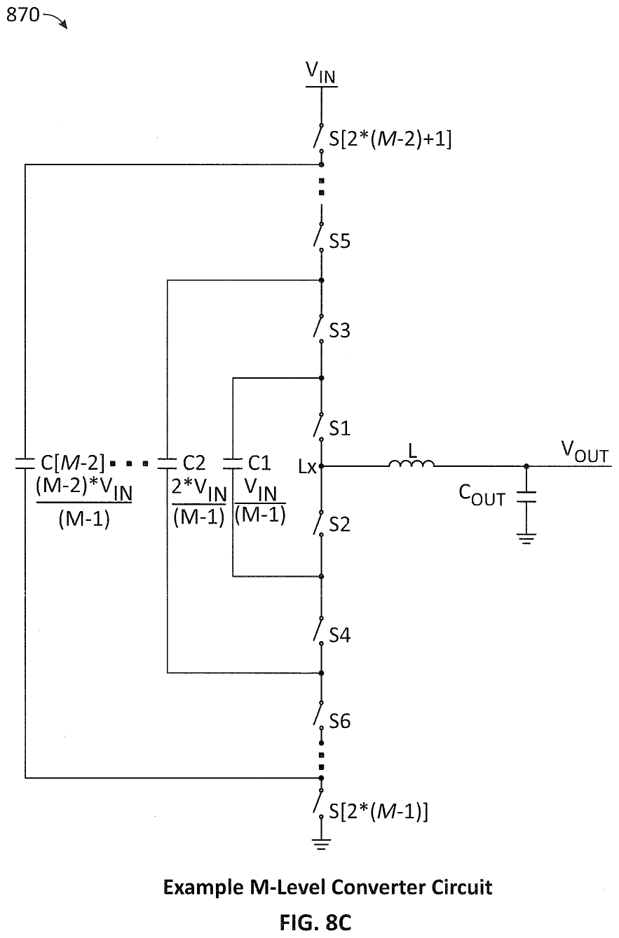

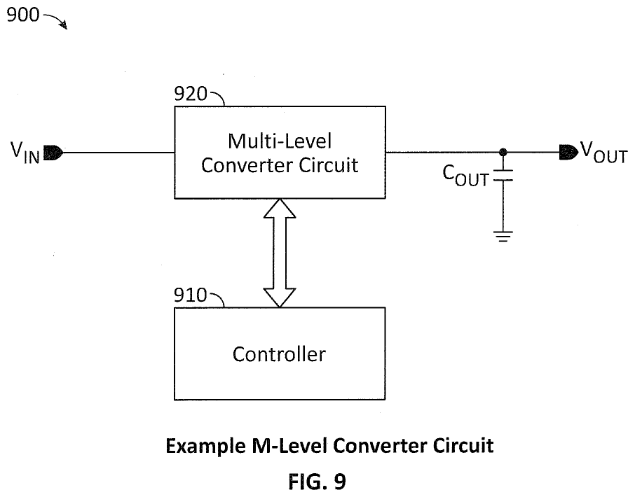

Referring to FIGS. 8A-8C, the converter circuit may be configured to switch between two or more switch states. One or more PWM duty cycle controllers may be provided to set the time in each switch state based on the voltage at VOUT. For example, FIG. 8A is a schematic diagram of a 3-level DC-to-DC buck converter circuit 800 that may be used as the converter circuit 920 of FIG. 9. A set of four switches, S1-S4, is series-coupled between VIN and circuit ground. A fly capacitor C1 is coupled in series with switches S3 and S4, and in parallel with switches S1 and S2. An inductor L1 is coupled to an output capacitor COUT and to a node Lx between switches S1 and S2, and the voltage across the output capacitor COUT is VOUT.

In the illustrated example, the presence of the single fly capacitor C1 in the converter circuit 800 enables four switch states that each generate one of three voltage levels at node Lx. In a first switch state, S2 and S4 are closed and S1 and S3 are open, effectively bypassing C1 and connecting Lx to circuit ground (voltage level at Lx=GND). In a second switch state, S2 and S4 are open and S1 and S3 are closed, effectively bypassing C1 and connecting Lx to V_{IN} (voltage level at Lx=VIN). In a third switch state S1 and S4 are open and S2 and S3 are closed, connecting C1 from V_{IN} to LX, and thus charging C1 with inductor L1 current flowing into a load. The voltage across C1 will be about VIN/2 and the voltage level at Lx will also equal about VIN/2. In a fourth switch state, S1 and S4 are closed and S2 and S3 are open, connecting C1 from Lx to GND and thus discharging C1 with inductor L1 current flowing to a load. The voltage across C1 will be about VIN/2 and the voltage level at Lx will also equal about VIN/2 (e.g., this may assume that C1 was previously charged in state three). Accordingly, the illustrated converter circuit 800 has two switch states that generate a voltage level of VIN/2 at the Lx node.

If the converter circuit 800 is toggled between switch states three and four (avoiding switch state two that bypasses the fly capacitor C1), the inductor L1 sees small jumps in the voltage level at Lx, going from GND to only VIN/2 and back to GND, which results in reduced voltage ripple across the inductor L1 and less filtering to smooth VOUT than a converter circuit with only S1 and S2 switches.

Adding additional series switches Sx and fly capacitors Cx to the 2-level converter circuit 800 increases the number of switch states and resulting voltage levels between V_{IN} and circuit ground that can be applied to the Lx node, thus generating an even smaller voltage ripple across the inductor L. This reduces the filtering requirements to get a smooth output voltage. For example, a 4-level DC-to-DC buck converter circuit (see, e.g., FIG. 8B) includes 6 series-coupled switches S1-S6 and two fly capacitors Cx (X=2). Consequently, a 4-level converter circuit can define 4 voltage levels (VIN, GND, ⅓VIN, and ⅔VIN) at node LX from 8 switch states (3 switch states result in the ⅓VIN level at Lx, and 3 other switch states result in the ⅔VIN level at Lx). For some applications, VOUT is set low enough that the voltage level at node Lx alternates between GND and the next higher voltage level available. For higher output voltages, the switching pattern may never use GND. For example, in a 4-level converter circuit, an output VOUT set to 0.5*VIN can be achieved by alternating the Lx node between ⅔ VIN and ⅓ V.

A different interpretation of a multi-level converter circuit is that the fly capacitors Cx create a charge-pump for the buck converter circuit. Unlike a standard charge-pump where the output is restricted to one output, a multi-level converter circuit allows the fly capacitors Cx to be coupled to create multiple intermediate voltages. For the 4-level example, the two fly capacitors each act as a ⅓ charge-pump with the additional benefit that any input voltage that is a sum of ⅓ ratios can be created, including V_{IN} and GND.

A multi-level converter circuit couples the fly capacitors Cx in different combinations in order to bring the voltage level at the Lx node down or up. As noted above, when a fly capacitor is used (i.e., not bypassed), the electrical energy flowing through that fly capacitor generally will either charge it or discharge it, which creates a control problem in maintaining an average voltage.

Resolving the charge-balance problem so as to maintain an average voltage across the single capacitor in a 3-level converter circuit will now be described. For example, in a 3-level converter circuit, one way to generate the Level-1 (GND) and Level-3 (VIN) voltage levels at the Lx node is to not use the fly capacitors C1 for these Lx voltage levels. However, for the Level 2 (VIN/2) voltage level at Lx, two separate switch states can be used: one switch state charges the capacitor (S3 and S2 closed, S1 and S4 open) and the other switch state discharges the capacitor (S3 and S2 open, S1 and S4 closed). The control of a 3-level converter circuit may operate such that each time the converter circuit switches states to Level-2, a controller can alternate between charging and discharging the single capacitor to maintain its voltage. A voltage comparator can be used to monitor the capacitor to help decide on a charging state or a discharging state. For instance, if the capacitor voltage is below VIN/2, then a controller would select charge (the third switch state), and if the capacitor voltage is above VIN/2, then the controller would select discharge (the fourth switch state).

Referring to FIGS. 8B, a 4-level converter circuit 830 (X=2) illustrates the charge-balance difficulty when more capacitors are present. A Level-1 voltage level (GND) and a Level-4 voltage level (VIN) at the Lx node are each determined by a single switch state. However, the Level-2 voltage level (⅓ VIN) and Level-3 voltage level (⅔ VIN) at Lx each can be achieved by any of three different switch states. At higher orders of a multi-level converter circuit (X>2), more switch states are possible for generating the intermediate levels between VIN and GND. The problem gets more complicated with a 5-level converter circuit (X=3). A Level-1 voltage level (GND) and a Level-5 voltage level (VIN) at the Lx node are each determined by a single switch state. However, the Level-2 voltage level (¼VIN) and Level-4 voltage level (¾ VIN) at Lx each can be achieved by any of four different switch states, the Level-3 voltage level (2/4 VIN) at Lx can be achieved by any of six different switch states.

As should be clear from these examples, determining a suitable charge-balance method can become exceedingly difficult as the complexity of a multi-level converter circuit increases. As previously noted, most conventional control methods rely on establishing a sequence of linked state-changes to try to achieve charge balance. Control systems based on long sequences of switch states generally assume that all system variables-such as input voltage and output current—are constant during the sequence. This is unrealistic for a real-world environment, where all system variables tend to be dynamic.

In a 2-Level example, the converter circuit switches between two switch states: S1 closed and S2 open (voltage level at L_{X}=V_{IN}), or S1 open and S2 closed (voltage level at L_{X}=GND). A PWM duty cycle controller sets the time in each switch state based on the voltage at V_{OUT}, which determines the amplitude of the average voltage at L_{X} (noting that, the average L_{X} voltage in theory is equal to the V_{OUT} average voltage, but that, due to parasitics, the L_{X} average voltage is higher and/or lower (for negative currents) than the V_{OUT} average). As can be appreciated, the inductor L sees large jumps in the voltage level at L_{X}, from GND to V_{IN} and back to GND. The resulting voltage ripple across the inductor L necessitates a significant amount of filtering to smooth V_{OUT}.

An alternative way of reducing the voltage ripple across the inductor L is to add more series switches as well as charge transfer capacitors as energy storage elements to transfer charge from V_{IN} to V_{OUT}. As noted above, such charge transfer capacitors are commonly known as “fly capacitors” or “pump capacitors” and may be external components coupled to an integrated circuit embodiment of a converter circuit. The presence of X fly capacitors Cx defines a multi-level capacitive converter circuit capable of generating M=X+2 voltage levels at node L_{X} from 2^{(X+1)} switch states.

FIG. 8C is schematic diagram of a generalized M-level multi-level converter cell 870 that may be used as the converter circuit 920 of FIG. 9. A set of switches, S1-S[2*(M−1)], is series-coupled between V_{IN} and circuit ground. The set of switches are organized in switch pairs: S1 & S2, S3 & S4, . . . . S[2*(M−2)+1] & S[2*(M−1)]. A set of M−2 fly capacitor Cx is coupled in series with certain respective switches, and in parallel with switches in between those switches. In terms of switch pairs, there are M−1 pairs of switches, or one more than the number of fly capacitors. An optional inductor Lis coupled to an output capacitor C_{OUT} and to a node L_{X} between switches S1 and S2, and again the voltage across the output capacitor C_{OUT} is V_{OUT}. The inductor L doubles as a virtual current source that facilitates movement of charge between the fly capacitors Cx. This creates a very efficient form of charge transfer, but introduces the problem of charge-balancing the fly capacitors Cx.

In various embodiments, each fly capacitor Cx has a first terminal coupled between an outer high-side switch S[2*x+1] and an inner high-side switch S[2*x−1], where “high-side” refers to the V_{IN} side of the converter circuit. Each fly capacitor Cx has a second terminal coupled between an outer low-side switch S[2*x+2] and an inner low-side switch S[2*x], where “low-side” refers to the circuit ground (GND) side of the converter circuit. Thus, for an M=3 multi-level converter cell, a first terminal of the single (X=1) fly capacitor C1 would be coupled between outer high-side switch S3 and inner high-side switch S1, and a second terminal of the capacitor C1 would be coupled between inner low-side switch S2 and outer low-side switch S4. Accordingly, each fly capacitor Cx within the multi-level converter cell 870 has four switches that can affect current flow through that fly capacitor Cx.

In some embodiments, a voltage detector, which may be a simple comparator-type circuit, is provided to sense the voltage across a corresponding fly capacitor Cx with respect to a reference voltage, V_{REF}, which represents a desired target voltage for the fly capacitor Cx. Every fly capacitor Cx may have a target average voltage in order to maintain proper output level. For an M-level converter and capacitor Cx, where x=1, 2, . . . [M−2], its target voltage is:

$$Vtarget [ Cx ] = {V}_{IN} * \frac{x}{M - 1}$$

The voltage detector may be configured to output a HIGH/LOW status signal, C_{Fx_H/L}, indicating with the voltage across the corresponding fly capacitor Cx is greater than V_{REF} or less than VREF. The C_{Fx_H/L} status signal is coupled to control circuitry for the switches associated with the fly capacitor Cx.

The control circuitry for the four switches that can affect current flow through a fly capacitor Cx set states for those switches in part as a function of the voltage across the fly capacitor Cx as measured by the associated voltage detector and conveyed by the C_{Fx_H/L}x status signal. Accordingly, for ease of understanding, it can be said that each fly capacitor Cx “controls” its own pairs of high-side and low-side switches. If it is assumed that current flow in the inductor is charging the output VOUT, there are four possible states that can be defined for the pairs of high-side and low-side switches for each fly capacitor Cx.

In a switch state in which the outer high-side and inner low-side switches associated with fly capacitor Cx are closed and all other associated switches are open, fly capacitor Cx would be in a charging configuration (whether or not charging actually occurs may depend on the switch states for other fly capacitors Cx). In a switch state in which the inner high-side and outer low-side switches associated with fly capacitor Cx are closed and all other associated switches are open, fly capacitor Cx would be in a discharging configuration (whether or not discharging actually occurs may depend on the switch states for other fly capacitors Cx). In a switching state in which the inner low-side and outer low-side switches associated with fly capacitor Cx are closed and all other associated switches are open, fly capacitor Cx would be bypassed. In a switching state in which the outer high-side and inner high-side switches associated with fly capacitor Cx are closed and all other associated switches are open, fly capacitor Cx would again be bypassed.

While each fly capacitor Cx can control both of its own pairs of high-side and low-side switches, in general, methods of control disclosed herein may utilize either the outer switches or the inner switches controllable by each corresponding capacitor. For example, referring to FIG. 8B, in “outer-switch” methods, fly capacitor C1 will control its outer switches S3 and S4, fly capacitor C2 will control its outer switches S5 and S6, etc. Conversely, for example, in “inner-switch” methods, fly capacitor C1 will control its inner switches S1 and S2, fly capacitor C2 will control its inner switches S3 and S4, etc. The switch states of either pair (inner or outer) of switches controlled by a fly capacitor Cx may be complementary—that is, no fly capacitor Cx closes or opens both of its high-side and low-side controlled switches at the same time. If each fly capacitor Cx controls its outer-switches, then no fly capacitor controls the left-over innermost switches S1 and S2. If instead each fly capacitor Cx controls its inner-switches, then no fly capacitor controls the left-over outermost switches S[2*(M−1)] and S[2*(M−2)+1]. Switch states for the left-over switches are also complementary.

FIG. 9 is a high-level block diagram of an example circuit that includes a power converter 900, in accordance with one or more embodiments of the present disclosure. In the illustrated example, the power converter 900 includes a converter circuit 920 and a controller 910. The converter circuit 920 and controller 910 may be configured to implement, for example, any of the multi-level power converter circuits as previously described with reference to FIGS. 1A-8C, and as described further herein. In the illustrated embodiment, the converter circuit 920 is configured to receive an input voltage VIN from a voltage source and transform the input voltage VIN into an output voltage VOUT. In some embodiments of the power converter 900, auxiliary circuitry (not shown), such as a bias voltage generator(s), a clock generator, a voltage control circuit, etc., may also be present and coupled to the converter circuit 920 and the controller 910.

The controller 910 receives a set of input signals and produces a set of output signals. Some of these input signals arrive along a signal path connected to the converter circuit 920. These input signals carry information that is indicative of the operational state of the converter circuit 920. The controller 910 may also receive a clock signal CLK (for synchronous converter circuits 920) and one or more external input/output signals I/O that may be analog, digital (encoded or direct signal lines), or a combination of both. Based upon the received input signals, the controller 910 produces a set of control signals back to the converter circuit 920 that control the internal components of the converter circuit 920 (e.g., internal switches, such as low voltage FETs/MOSFETs) to cause the converter circuit 920 to boost or buck VIN to VOUT. In some embodiments, an auxiliary circuit (not shown) may provide various signals to the controller 910 (and optionally directly to the converter circuit 920), such as the clock signal CLK, the input/output signals I/O, as well as various voltages, such as a general supply voltage VDD and a transistor bias voltage VBIAS.

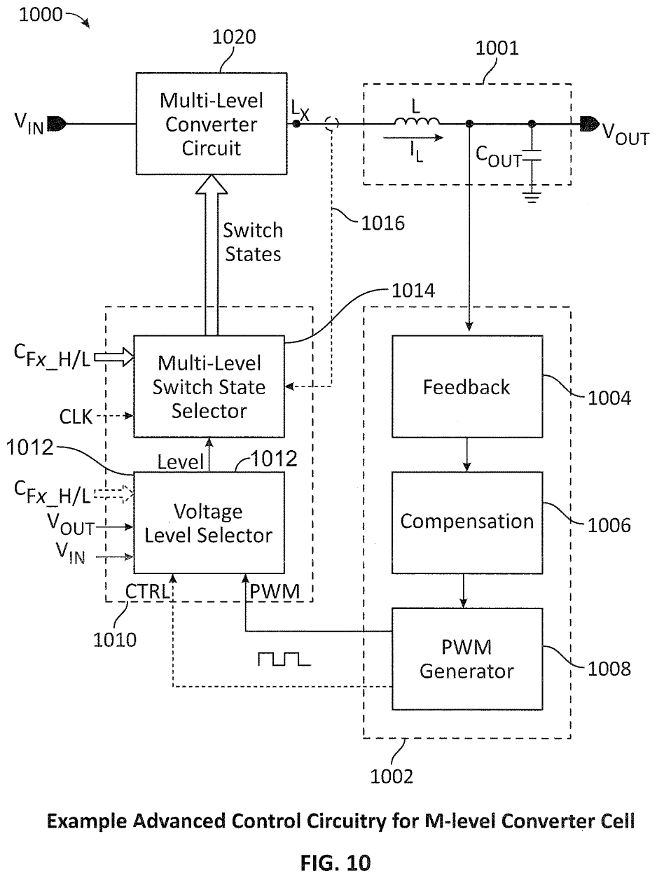

FIG. 10 is a block diagram of one embodiment of advanced control circuitry 1000 for an M-level converter cell 1000 such as the generalized version depicted in FIG. 8B. The M-level converter cell 1020 is shown coupled to an output block 1001 comprising an inductor L and an output capacitor C_{OUT} (conceptually, the inductor L also may be considered as being included within the M-level converter cell 1020). The advanced control circuitry 1000 functions as a control loop coupled to the output of the M-level converter cell 1020 and to switch control inputs of the M-level converter cell 1020. In general, the advanced control circuitry 1000 is configured to monitor the output (e.g., voltage and/or current) of the M-level converter cell 1020 and dynamically generate a set of switch control inputs to the M-level converter cell 1020 that attempt to stabilize the output voltage and/or current at specified values, taking into account variations of V_{IN} and output load. In alternative embodiments, the advanced control circuitry 1000 may be configured to monitor the input of the M-level converter cell 1020 (e.g., voltage and/or current) and/or an internal node of the M-level converter cell 1020 (e.g., the voltage across one or more fly capacitors or the current through one or more power switches). Accordingly, most generally, the advanced control circuitry 1000 may be configured to monitor the voltage and/or current of a node (e.g., input terminal, internal node, or output terminal) of the M-level converter cell 1020. The advanced control circuitry 1000 may be incorporated into, or separate from, the overall controller for a power converter 100 embodying the M-level converter cell 1020.

A first block comprises a feedback controller 1002, which may be a traditional controller such as a fixed frequency voltage mode or current mode controller, a constant-ON-time controller, a hysteretic controller, or any other variant. The feedback controller 1002 is shown as being coupled to V_{OUT} from the M-level converter cell 1020. In alternative embodiments, the feedback controller 1002 may be configured to monitor the input of the M-level converter cell 1020 and/or an internal node of the M-level converter cell 1020. The feedback controller 1002 produces a signal directly or indirectly indicative of the voltage at VOUT that determines in general terms what needs to be done in the multi-level converter cell 1020 to maintain desired values for VOUT: charge, discharge, or tri-state (i.e., open, with no current flow).

In the illustrated example, the feedback controller 1002 includes a feedback circuit 1004, a compensation circuit 1006, and a PWM generator 1008. The feedback circuit 1004 may include, for example, a feedback-loop voltage detector which compares V_{OUT} (or an attenuated version of V_{OUT}) to a reference voltage which represents a desired V_{OUT} target voltage (which may be dynamic) and outputs a control signal to indicate whether V_{OUT} is above or below the target voltage. The feedback-loop voltage detector may be implemented with a comparison device, such as an operational amplifier (op-amp) or transconductance amplifier (gm amplifier).

The compensation circuit 1006 is configured to stabilize the closed-loop response of the feedback controller 1002 by avoiding the unintentional creation of positive feedback, which may cause oscillation, and by controlling overshoot and ringing in the step response of the feedback controller 1002. The compensation circuit 1006 may be implemented in known manner, and may include LC and/or RC circuits.

The PWM generator 1008 generates the actual PWM control signal which ultimately sets the duty cycle of the switches of the multi-level converter cell 1020. In addition, in some embodiments, the PWM generator 1008 may pass on additional optional control signals CTRL indicating, for example, the magnitude of the difference between V_{OUT} and the reference voltage (thus indicating that some levels of the M-level converter cell 1020 should be bypassed to get to higher or lower levels), and the direction of that difference (e.g., whether V_{OUT} is greater than or less than the reference voltage). In other embodiments, the optional control signals CTRL can be derived from the output of the compensation circuit 1006, or from the output of the feedback circuit 1004, or from a separate comparator (not shown) coupled to, for example, V_{OUT}. One purpose of the optional control signals CTRL is for advanced control algorithms, when it may be beneficial to know how far away V_{OUT} is from a target output voltage, thus allowing faster charging of the inductor L if the V_{OUT} is severely under regulated.

A second block comprises a multi-level controller 1010, the primary function of which is to select the switch states that generate a desired V_{OUT} while maintaining a charge-balance state on the fly capacitors within the M-level converter cell 1020 every time an output voltage level is selected, regardless of what switch state or states were used in the past.

The multi-level controller 1010 includes a Voltage Level Selector 1012 which receives the PWM control signal and the additional control signals CTRL if available. In addition, the Voltage Level Selector 1012 may be coupled to V_{OUT} and/or VIN, and, in some embodiments, to the HIGH/LOW status signals, C_{Fx_H/L}, from the voltage detectors coupled to corresponding fly capacitors Cx within the M-level converter cell 1020. A function of the Voltage Level Selector 1012 is to translate the received signals to an output voltage Target Level (e.g., on a cycle-by-cycle basis). The Voltage Level Selector 1012 typically will consider at least V_{OUT} and V_{IN} to determine which Target Level should charge or discharge the output of the M-level converter cell 1020 with a desired rate. For example, in a 6-level converter circuit, the available Target Levels are Level-1 (GND), Level-2 (⅕V_{IN}), Level-3 (⅖V_{IN}), Level-4 (⅗V_{IN}), Level-5 (⅘V_{IN}), and Level-6 (V_{IN}), which may be represented as a count value from 1-6 (or 0-5).

As an example, in a 4-Level converter circuit, if V_{IN}=12V and V_{OUT} nominally should be 3V, then the Voltage Level Selector 1012 may indicate that a Target Level of “2” can be selected, which results in a ⅓ V_{IN} voltage level at L_{X} (i.e., 4V). The PWM control signal sets a duty cycle between that Target Level and another Target Level (e.g., GND) so that the average voltage level at L_{X} will be about 3V.

In general, for steady-state operations, the Target Level voltage closest to V_{OUT} that either charges or discharges the inductor L may be selected for simplicity of the selection algorithm. In general, for transient response, a Target Level that is higher (for charging) or lower (for discharging) than the closest Target Level may be selected to quickly charge or discharge the inductor L. The Voltage Level Selector 1012 may be implemented, for example, as a look-up table (LUT) or as comparison circuitry and combinatorial logic or more generalized processor circuitry. In some embodiments, the Voltage Level Selector 1012 can implement advanced methods (described below) that try to speed up charging or discharging based on additional factors, such as inductor voltage drop, load transients, the magnitude of output deviations, and/or external input signals from external sources. The output of the Voltage Level Selector 1012 may include duty cycle information (e.g., derived from the input PWM control signal) as well as switch state.

The output of the Voltage Level Selector 1012 is coupled to a Multi-Level Switch State Selector 1014, which generally would be coupled to the status signals, C_{Fx_H/L}, from the voltage detectors for the fly capacitors Cx. Taking into account the Target Level generated by the Voltage Level Selector 1012, the Multi-Level Switch State Selector 1014 determines a pattern of switch states for the desired output level that generally achieves charge-balancing the fly capacitors Cx. The Multi-Level Switch State Selector 1014 may be implemented, for example, as comparison circuitry and combinatorial logic, as a look-up table (LUT), or as more generalized processor circuitry. The output of the Multi-Level Switch State Selector 1014 is coupled to the switches of the multi-level converter cell 1020 (through appropriate level-shifter circuits and drivers circuits, as may be needed for a particular converter cell) and includes a pattern of switch state settings determined by the Multi-Level Switch State Selector 1014. The pattern of switch state settings selects the configuration of the switches within the multi-level converter cell 1020.

In general (but not always), for PWM-based control systems, the Voltage Level Selector 1012 and the M-level Switch State Selector 1014 only change their states when the PWM signal changes. For example, when the PWM signal goes high, the Voltage Level Selector 1012 selects which level results in charging of the inductor L and the M-level Switch State Selector 1014 sets which version to use of that level. Then when the PWM signal goes low, the Voltage Level Selector 1012 selects which level can discharge the inductor L and the M-level Switch State Selector 1014 sets which version of that level to use. Thus, the Voltage Level Selector 1012 and the M-level Switch State Selector 1014 generally only change states when the PWM signal changes (the PWM signal is in effect their clock signal). However, there may be situations or events where it is desirable for the CTRL signal to change the state of the Voltage Level Selector 1012. Further, there may be situations or events where it is desirable for the C_{Fx_H/L} status signal(s) to cause the M-level Switch State Selector 1014 to select a particular configuration of power switch settings, such as when a severe mid-cycle imbalance occurs. In some embodiments, it may be useful to include a timing function that forces the M-level Switch State Selector 1014 to re-evaluate the optimal version of the state periodically, for example, in order to avoid being “stuck” at one level for a very long time, potentially causing charge imbalances.

One notable benefit of the control circuitry shown in FIG. 10 is that it enables generation of voltages in boundary zones between voltage levels, which represent unattainable output voltages for conventional multi-level DC-to-DC converter circuits.

In alternative unregulated charge-pumps embodiments, the feedback controller 1002 and the Voltage Level Selector 1012 may be omitted, and instead a clock signal CLK may be applied to the M-level Switch State Selector 1014. The M-level Switch State Selector 1014 would generate a pattern of switch state settings that periodically charge balances the fly capacitors Cx regardless of what switch state or states were used in the past (as opposed to cycling through a pre-defined sequency of states). This ensures that if V_{IN} changes or anomalous evens occur, the system generally always seeks charge balance for the fly capacitors Cx.

In some embodiments, the M-level Switch State Selector 1014 may take into account the current IL flowing through the inductor L by way of an optional current-measurement input 1016, which may be implemented in conventional fashion.

In an M-level multi-level converter circuit, the configuration of switches that achieves Level-1 (e.g., GND) or Level-M (e.g., V_{IN}) effectively bypasses the fly capacitors Cx. Conversely, for all intermediate voltage levels, at least one fly capacitor Cx is coupled to VOUT and there are always at least two configurations of switches that can achieve any intermediate voltage level. For any particular intermediate voltage level, at least one configuration of switches results in charging the associated fly capacitor and at least one other configuration of switches results in discharging the associated fly capacitor. One aspect of the present disclosure is the realization that any achievable output voltage V_{OUT} requiring intermediate voltage levels can be attained by dynamically selecting patterns of switch configurations—that is, by selecting switch configurations without regard to or memory of the switch configurations of any previous switching cycle—to select appropriate Levels, and doing so in a way that purposefully selects either charging or discharging switch configurations that also balance charge across the fly capacitors Cx.

Embodiments of the disclosure use the following approach for positive inductor L current (charging V_{OUT}):
(1) a fly capacitor Cx that needs charging will be set to close its charging switch (the outer high-side switch in outer-switch control methods, or the inner low-side switch for inner-switch control methods); and
(2) a fly capacitor Cx that needs discharging will be set to close its discharging switch (the outer low-side switch for outer-switch control methods, or the inner high-side switch for inner-switch control methods).

For negative inductor L current (discharging V_{OUT}), the selection of switches inverts. Accordingly:
(1) a fly capacitor Cx that needs charging will be set to close its charging switch (the outer low-side switch in outer-switch control methods, or the inner high-side switch for inner-switch control methods); and
(2) a fly capacitor Cx that needs discharging will be set to close its discharging switch (the outer high-side switch for outer-switch control methods, or the inner low-side switch for inner-switch control methods).

Note again that whether or not charging actually occurs for a particular fly capacitor Cx generally depends on the switch states for all other fly capacitors. For a fly capacitor C(x) to actually charge or discharge, the next inward (if one exists) fly capacitor C(x−1) (for outer-switch control methods) or the previous outward (if one exists) fly capacitor C(x+1) (for inner-switch control methods) must be set to the opposite state (i.e., discharge or charge) so that a bypass situation does not occur.

For any multi-level converter circuit of order M that can create M voltage levels—i.e., Level−1 (e.g., GND) through Level-M (e.g., V_{IN})—then the following switch count rules apply for any Level-m:
(1) M−m low-side switches must be set to be closed (ON);
(2) m−1 high-side switches must be set to be closed (ON); and
(3) switches that are not required to be ON must be set to be OFF (open).

With these switch count rules in mind, the following generalized capacitor control method applies for each state change of the Multi-Level Switch State Selector 1014:
Step 1) Select a fly capacitor that has not previously been selected;
Step 2) If the voltage of the selected fly capacitor is above its Vtarget and there are remaining (i.e., not been set by this method in this cycle) low-side or high-side switches that can be set to be closed to enable a discharge path for the selected fly capacitor, then set those switches that enable a discharge path for the selected fly capacitor to be closed, decrement one or more appropriate counters (e.g., for the number of low-side switches set to be closed and the number of high-side switches set to be closed), and flag the current fly capacitor as “done” (i.e., as having been selected); otherwise (since the voltage of the selected fly capacitor is below its Vtarget) set the switches that enable a charging path for the selected fly capacitor to be closed and flag the current fly capacitor as “done”;
Step 3) Loop to Step 1 until all fly capacitors have been selected;
Step 4) For the remaining pair of left-over switches, set the high-side switch or the low-side switch to be closed based on the switch count rules and the counter values.

With the above generalized capacitor control method, more specific multi-level charge-balancing control methods can be created. Examples can be found, for example, in U.S. Patent Publication No. 20230148059, which is incorporated by reference herein in its entirety.

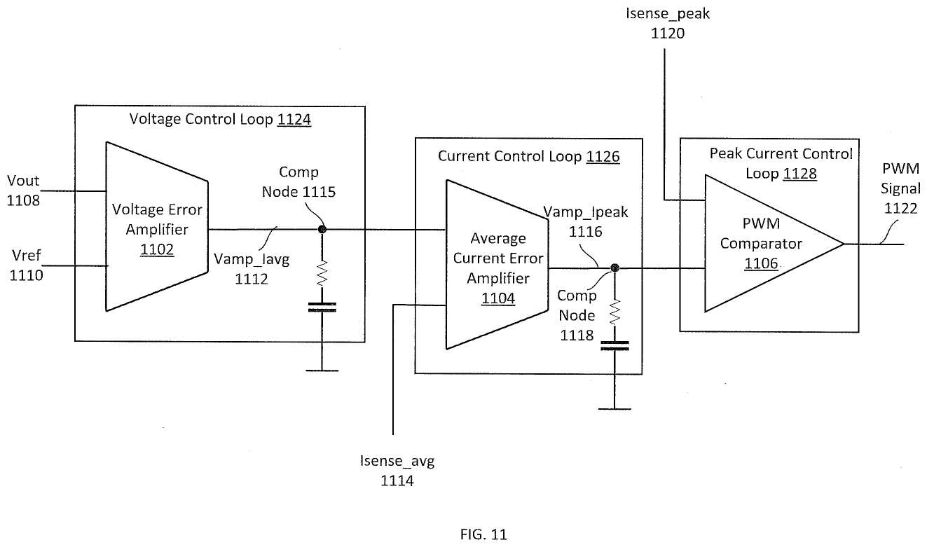

FIG. 11 is a block diagram 1100 of a controller, according to some embodiments. An exemplary controller may be controller 1002. Controller 1002 may regulate and control different system variables, including output voltage (V_{OUT}), average current (I_{AVE}), and peak current (I_{PEAK}). An output voltage (V_{OUT}) may be an output voltage of the multi-level converter. An average current (I_{AVE}) may be a current measured across one or more switches of the multi-level converter over a predetermined amount of time. Peak current (I_{PEAK}) may be a current measured across one or more switches of the multi-level converter at certain time. Multiple peak current (I_{PEAK}) measurements may be used to determine the average current (I_{AVE}) over a predetermined amount of time. In particular, controller 1002 may regulate and control different system variables of the multi-level power converter during different stages of the battery charging application.

Controller 1002 illustrated in FIG. 11 may include multiple amplifiers, such as a first amplifier and a second amplifier. The first amplifier may be a voltage error amplifier 1102 and a second amplifier may be an average current error amplifier 1104. Voltage error amplifier 1102 and average current error amplifier 1104 may be operational transconductance amplifiers. Voltage error amplifier 1102 may determine an error between voltage inputs, such as output voltage (V_{OUT}) that may be an output voltage of the multi-level converter and a reference voltage that may be sensed using a sensor or a load. Average current error amplifier 1104 may be a type of current error amplifier that determines an error between two inputs representing currents. In case of average current error amplifier 1104, the inputs may represent an average current (I_{AVE}) that passes through the multi-level converter and may be regulated and a reference average current that may be sensed using one of the sensors. Additionally, controller 1002 may include a comparator, such as pulse width modulated (PWM) comparator 1106. A comparator may compare two inputs and generate an output indicating which input is greater. The PWM comparator 1106 may be a comparator that compares the two inputs and generates a PWM signal that may be used to set a duty cycle. In case of PWM comparator 1106 the inputs may represent the peak current (I_{PEAK}) that may be regulated and the sensed peak current (I_{PEAK}) that may be sensed using one or more sensors. The voltage error amplifier 1102, the average current error amplifier 1104, and the PWM comparator 1106 may be arranged in sequence, such that an output signal of the voltage error amplifier 1102 may be an input signal into the average current error amplifier 1104, and an output signal of the average current error amplifier 1104 may be an input signal into PWM comparator 1106.

In some embodiments, voltage error amplifier 1102, average current error amplifier 1104, and PWM comparator 1106 may receive a signal representing a system variable to be regulated and a signal representing a reference value for the system variable that may be sensed using one or more sensors. For example, voltage error amplifier 1102 may receive a system variable that may be an output voltage (V_{OUT}) 1108 and a reference voltage (V_{REF}) 1110 and determine an error between output voltage (V_{OUT}) 1108 and a reference voltage (V_{REF}) 1110. Output voltage (V_{OUT}) may be an output voltage to be regulated by the multi-level converter. The reference voltage (V_{REF}) 1110 may be a reference voltage that is a voltage across a load, e.g., a battery. The voltage error amplifier 1102 may use output voltage (V_{OUT}) 1108 and reference voltage (V_{REF}) 1110 to generate an output signal. The output signal may correspond to an error between output voltage (V_{OUT}) 1108 and reference voltage (V_{REF}) 1110 and represent an average current (I_{AVG}) and may be referred to as a Vamp_Iavg 1112 signal. The Vamp_Iavg signal 1112 may represent a minimum of the output voltage (V_{OUT}) 1108 and reference voltage (V_{REF}) 1110 or an error between output voltage (V_{OUT}) 1108 and reference voltage (V_{REF}) 1110, and may correspond to an average current (I_{AVG}) to be regulated by the multi-level converter. The value corresponding to the Vamp_Iavg signal 1112 may be measured at the comparison node or comp node 1115. When comp node 1115 represents an average current, the error between output voltage (V_{OUT}) 1108 and reference voltage (V_{REF}) 1110 may be an indication to controller 1002 to increase the average current (I_{AVG}).

In some embodiments, voltage error amplifier 1102 may be included in a circuit referred to as a voltage control loop 1124. Voltage control loop 1124 may control the output voltage (V_{OUT}) generated by the multi-level converter. Typically, voltage control loop 1124 may be a more precise but a slow loop when compared to other loops in controller 1002.

As discussed above, Vamp_Iavg signal 1112 that is an output of voltage error amplifier 1102 may be an input to average current error amplifier 1104. For example, average current error amplifier 1104 may receive the Vamp_Iavg signal 1112 that may correspond to an average current (I_{AVG}) to be regulated and an average sensed current (I_{SENSE_AVG}) signal 1114 and determine an error between average current (I_{AVG}) and average sensed current (I_{SENSE_AVG}). The average sensed current (I_{SENSE_AVG}) may be sensed using a sensor that senses an average current across switches of the multi-level converter. For example, switches S3 and S4 of the 3-level converter discussed in FIG. 8A and switches S5 and S6 of the 4-level converter discussed in FIG. 8B may be sensed to determine the average sensed current (I_{SENSE_AVG}).

The average current error amplifier 1104 may use Vamp_Iavg signal 1112 and average sensed current (I_{SENSE_AVG}) signal 1114 to generate an output signal that corresponds to an error between average current (I_{AVG}) and average sensed current (I_{SENSE_AVG}). The output signal may be a Vamp_Ipeak signal 1116 representing a peak current (I_{PEAK}). The peak current (I_{PEAK}) may be a peak current to be regulated by the multi-level converter. The Vamp_Ipeak signal 1116 may be a minimum of or an error between the average current (I_{AVG}) corresponding to the Vamp_lavg signal 1112 and an average sensed current (I_{SENSE_AVG}) corresponding to average sensed current (I_{SENSE_AVG}) signal 1114. The value corresponding to the Vamp_Ipeak signal 1116 may be measured at the comparison node or comp node 1118. The error between the average current (I_{AVG}) and the sensed average current (I_{SENSE_AVG}) may be an indication to controller 1002 to increase the peak current (I_{PEAK}).

In some embodiments, average current error amplifier 1104 may be included in a circuit referred to as a current control loop 1126. The current control loop 1126 may regulate the average current (I_{AVG}) used by a system, such as the multi-level converter. Typically, current control loop 1126 may be a less precise but a faster loop when compared to other loops in controller 1002, such as voltage control loop 1124.

As discussed above, Vamp_Ipeak signal 1116 that is an output of average current error amplifier 1104 may be an input to PWM comparator 1106. For example, PWM comparator 1106 may receive Vamp_Ipeak signal 1116 that may correspond to the peak current (I_{PEAK}) to be regulated and a sensed peak current (I_{SENSE_PEAK}) signal 1120. PWM comparator 1106 may compare the peak current (I_{PEAK}) to the sensed peak current (I_{SENSE_PEAK}) and generate a PWM signal based on the comparison. The pulse width modulation signal may set the duty cycle. The sensed peak current (I_{SENSE_PEAK}) may be sensed using sensors that sense current across switches of multi-level converters discussed in FIGS. 8A and 8B. For example, switches S3 and S4 of the 3-level converter discussed in FIG. 8A and switches S5 and S6 of the 4-level converter discussed in FIG. 8B may be sensed to determine the sensed peak current (I_{SENSE_PEAK}). In some instances the sensed peak current (I_{SENSE_PEAK}) may also be mixed with a slope compensation waveform. The slope compensation waveform may be a triangular or sawtooth waveform, ramp voltage waveform, or a portion of the ramp voltage waveform and may mixed with the sensed peak current (I_{SENSE_PEAK}) to make the sensed peak current (I_{SENSE_PEAK}) more stable.

The PWM comparator 1106 may use Vamp_Ipeak signal 1116 and sensed peak current (I_{SENSE_PEAK}) signal 1120 to generate a PWM signal 1122. The PWM signal 1122 may be a pulse width modulation signal that indicates whether the peak current (I_{PEAK}) corresponding to Vamp_Ipeak signal 1116 or sensed peak current (I_{SENSE_PEAK}) corresponding to the sensed peak current (I_{SENSE_PEAK}) signal 1120 is greater. PWM signal 1122 may be a digital signal that may set a duty cycle as discussed in FIG. 10. For example, PWM signal 1122 may set a duty cycle when the multi-level converter circuit changes zones, such as from a first zone to a second zone, from the second zone to a third zone, from the third zone to a fourth zone, or vice versa.

In some embodiments, PWM comparator 1106 may be included in a circuit referred to as a peak current control loop 1128. The peak current control loop 1128 may regulate the peak current (I_{PEAK}) used by a system, such as the multi-level converter.

As discussed above, average sensed current (I_{SENSE_AVG}) and sensed peak current (I_{SENSE_PEAK}) may be measured at a multi-level converter. For simplicity, the embodiments below discuss measuring average sensed current (ISENSE AVG) and sensed peak current (I_{SENSE_PEAK}) using a four-level converter illustrated in FIG. 8B, though the embodiments are applicable to other M-Level converters. As illustrated in FIG. 8B, the four-level converter includes six switches, S1-S6. The average sensed current (I_{SENSE_AVG}) and sensed peak current (I_{SENSE_PEAK}) may be measured using the first and last outer switches S5 and S6 that may operate as a pair. In some embodiments, the average sensed current (I_{SENSE_AVG}) and sensed peak current (I_{SENSE_PEAK}) correspond to the average and peak current across the inductor of the multi-level converter. In the multi-level converter switches S5 and S5 operate as a pair, such that when S5 switch is on, S6 switch is off, and vice versa. Accordingly, either switch S5 or switch S6 is alternatively conducting current that passes through the inductor. Further, the current that passes through switch S5 and S6 also passes through the inductor. Thus it is possible to measure the average current and peak current at switches S5 and S6 instead of the inductor.

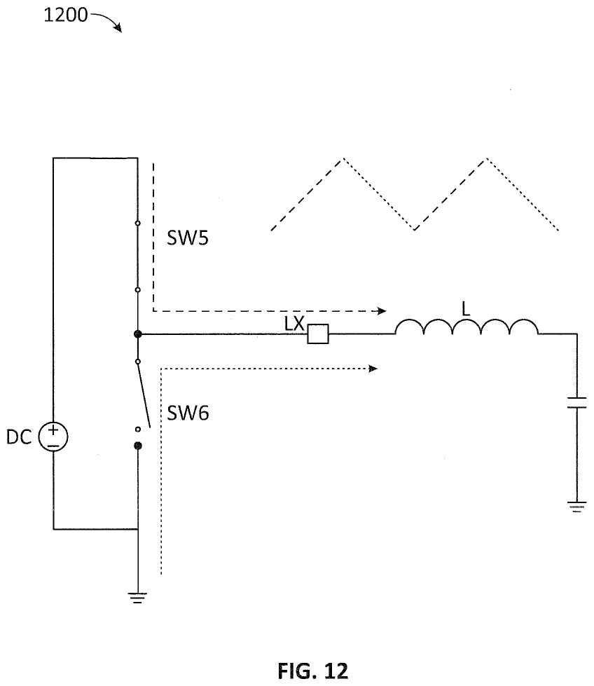

As discussed above, switch S5 and S6 do not conduct the current simultaneously, but alternatively, which results in a triangular current waveform. FIG. 12 is a diagram of an example average current across an inductor, according to some embodiments. As illustrated in FIG. 12, the current increases and when switch S5 is on and switch S6 is off, and the current decreases when switch S6 is on and switch 5 is off.

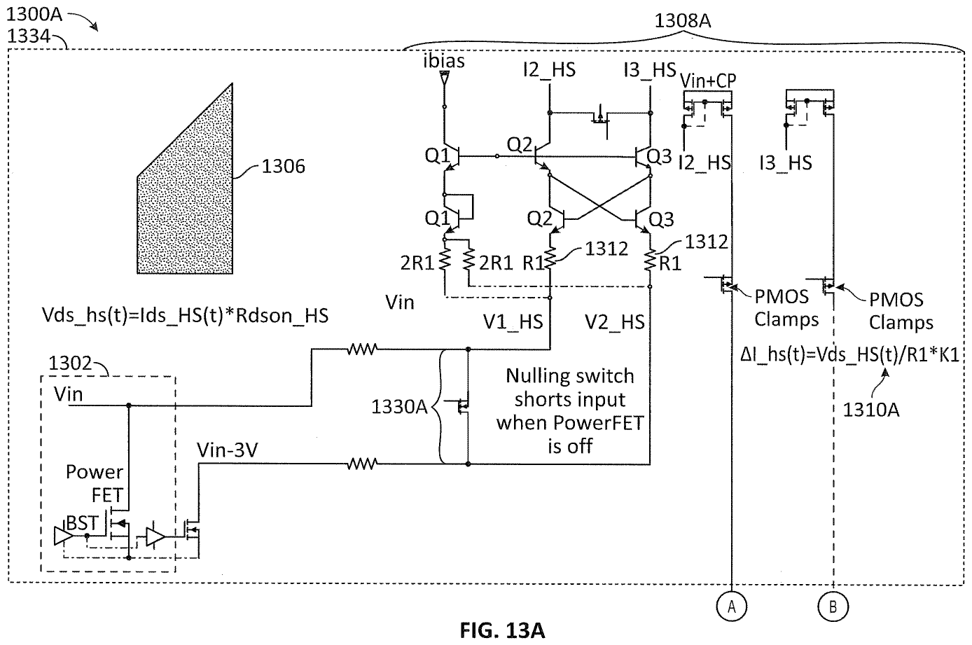

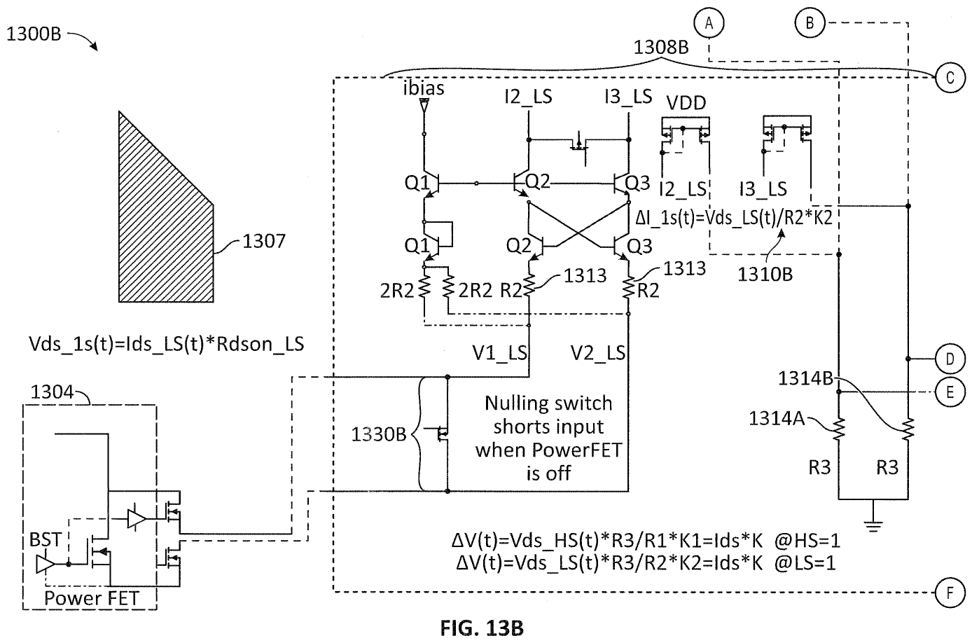

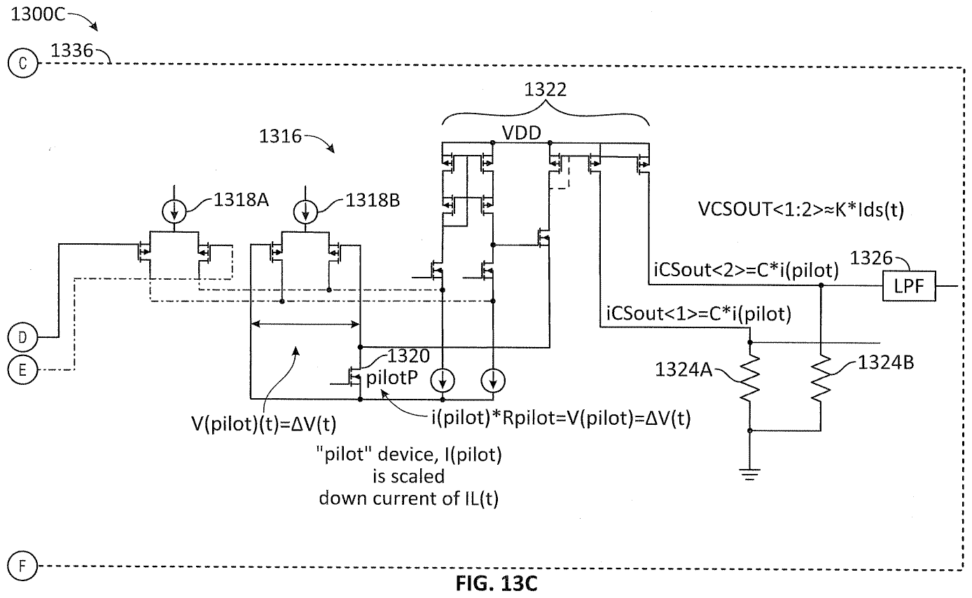

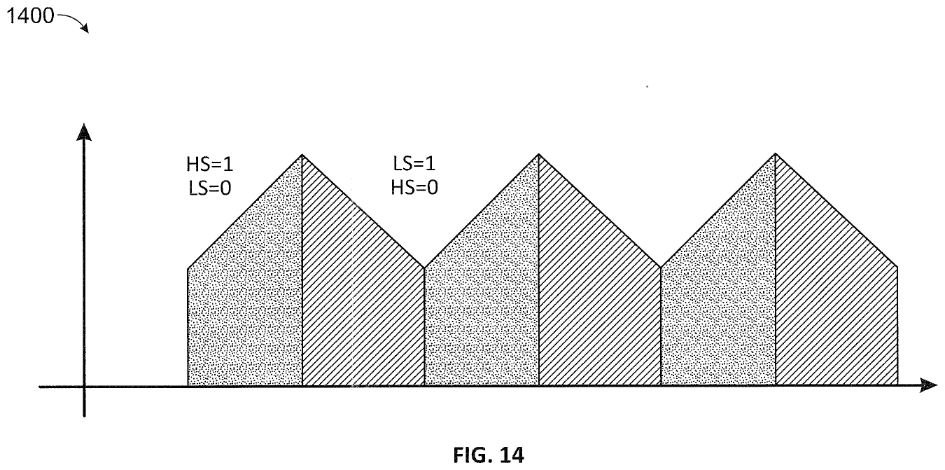

FIGS. 13A-13C are circuit diagrams 1300A-C for determining an average current and a peak current, according to some embodiments. FIGS. 13A-13C illustrate a single circuit over three diagrams. FIG. 13A illustrates an S5 switch at an S5 switch circuit 1302 and FIG. 13B illustrates an S6 switch as an S6 switch circuit 1304. S5 switch circuit 1302 and S6 switch circuit 1304 each include a power device, e.g., an FET transistor, that powers the S5 and S6 switches. When S5 switch circuit 1302 is on (and S6 switch circuit 1304 is off), the S5 switch circuit 1302 may conduct current that increases linearly, as shown in FIG. 12. The current also creates a voltage waveform 1306. When S6 switch circuit 1304 is on (and S5 switch circuit 1302 is off), the S6 switch circuit 1304 may conduct current that decreases linearly and creates a voltage waveform 1307. Thus, as S5 switch circuit 1302 and S6 switch circuit 1304 alternatively turn on and off, S5 switch circuit 1302 and S6 switch circuit 1304 create a voltage waveform shown in FIG. 14.

When S5 switch circuit 1302 is on, the voltage across the switch may be as follows:

Vds_hs(t)=Ids_HS(t)*Rdson_HS Equation (1)

When S6 switch circuit 1304 is on, the voltage across the switch may be as follows:

Vds_ls(t)=Ids_LS(t)*Rdson_LS Equation (2)

To measure the average current and peak current, FIGS. 13A-C include a mirror circuitry 1308A and a mirror circuitry 1308B. Mirror circuitry 1308A maybe associated with S5 switch circuit 1302 and mirror circuitry 1308B may be associated with S6 switch circuit 1304. Mirror circuitry 1308A may operate in a high voltage domain, and may be at or slightly below input voltage (V_{IN}), which in some cases may be around 60 volts. In some instances, mirror circuitry 1308A may operate at a voltage above the input voltage (V_{IN}), such as when the input voltage (V_{IN}) may be combined with a charge pump. Mirror circuitry 1308B may operate in a low voltage domain, which may be between voltage VDD, which may be below 5 volts, and zero volts.

The mirror circuitry 1308A may create a differential current 1310A that flows through the mirror circuitry 1308A. The differential current 1310A may be current I2—current I3 (or vice versa) shown in mirror circuitry 1308A. Differential current 1310A may be associated with S5 switch circuit 1302. Differential current 1310A may be equal to the voltage across S5 switch circuit 1302 divided by a ratio of an internal resister R1 1312 in mirror circuitry 1308A and K1 (K1 is a parameter of the internal resister R1 1312) as follows:

ΔI_hs(t)=Vds_HS(t)/R1*K1 Equation (3)

When S5 switch circuit 1302 is on, the differential current 1310A flows through resistors R3 1314A-B, creating a differential voltage at resistors R3 1314A-B as follows:

ΔV(t)=Vds_HS(t)*R3/R1*K1=Ids*K Equation (4)

The differential voltage may be voltage at resistor R3 1314A-voltage at resistor R3 1314B or vice versa.

The mirror circuitry 1308B may create a differential current 1310B that flows through the mirror circuitry 1308B. The differential current 1310B may be current I2—current I3 (or vice versa) shown in mirror circuitry 1308B. Differential current 1310B may be associated with S6 switch circuit 1304. Differential current 1310B may be equal to the voltage across S6 switch circuit 1304 divided by a ratio of an internal resister R2 1313 in mirror circuitry 1208B and K2 (K2 is a parameter of the internal resister R2 1313) as follows:

ΔI_ls(t)=Vds_LS(t)/R2*K2 Equation (5)

When S6 switch circuit 1304 is on, the differential current 1310B is applied to resistors R3 1314A-B, creating a differential voltage at resistors R3 1314 as follows:

ΔV(t)=Vds_LS(t)*R3/R2*K2=Ids*K Equation (6)

The differential voltage may be voltage at resistor R3 1314A-voltage at resistor R3 1314B or vice versa.

As S5 switch circuit 1302 and S6 switch circuit 1304 alternate between turning on and off, the change in the differential voltage at resistors R3 1314 varies between Equations (4) and (6). Equations (4) and (6) re-create the shape and timing of the voltage waveform shown in FIG. 14, but with different magnitude and values, and at a differential voltage.

A circuit 1316 in FIG. 13C may convert the differential voltage shown in Equations (4) and (6) into a voltage for measuring average current and peak current. Circuit 1316 includes differential pair inputs 1318A and 1318B, and a pilot device 1320. Differential pair inputs 1318A and 1318B may cause the differential voltage across resistors 1314A-B to create a voltage across the pilot device 1320 such that the voltage across pilot device 1320 is equal (or approximately equal) to the differential voltage across resistors 1314A-B as follows:

V(pilot)(t)=ΔV(t) Equation (7)

Pilot device 1320 may be a transistor or another device that matches power devices in S5 switch circuit 1302 and S6 switch circuit 1304. Typically, pilot device 1320 may be a scaled down device from power devices in S5 switch circuit 1302 and S6 switch circuit 1304.

The current that passes through pilot device 1320 may be proportional to the differential voltage across resistors 1314A-B, and is as follows:

i(pilot)*Rpilot=V(pilot)=ΔV(t) Equation (8)

The Rpilot may be a resistor in the pilot device 1320 and i(pilot) may be the current that passes through pilot device 3120.

As discussed above, the differential voltage across resistors 1314A-B represents a switch current across S5 switch circuit 1302 and a switch current across S6 switch circuit 1304. As also discussed above, the switch current also represents a current across an inductor of the multi-level converter. Accordingly, the current that passes through pilot device 1320 represents the current of the inductor in the multi-level converter.

Further, the pilot device 1320 may track the power devices of S5 switch circuit 1302 and S6 switch circuit 1304, such that the behavior of pilot device 1320 and power devices of S5 switch circuit 1302 and S6 switch circuit 1304 changes similarly with the system changes, such as with changes in temperature. Additionally, pilot device 1320 and power devices of S5 switch circuit 1302 and S6 switch circuit 1304 may also have the same orientation, be placed in close proximity from each other, and behave similarly.

In some embodiments, the current that passes through pilot device 1320 may be a constant and scaled down value of the switch current and the inductor current.

Circuit 1316 may include a mirror circuit 1322 that may pass the current from the pilot device 1320 to resistors 1324A and 1324B. The current passed through resister 1324A may be:

iCSout<1>=C*i(pilot) Equation (9)

and the current passed through resistor 1324B may be:

iCSout<2>=C*i(pilot) Equation (10)

The voltage across resistors 1324A-B may represent the switch current and the inductor current as follows:

VCSOUT<1:2>≈K*Ids(t) Equation (11)

A low pass filter (LPF) 1326 may measure the current across resistors 1324A-B. LPF 1326 may average the current across resistors 1324A-B to determine the average current. LPF 1326 may be a resistor/capacitor (RC) filter or another type of a filter. LPF 1326 may also be tunable to the frequency of the multi-level converter. The peak current may be measured at the resistor 1324 and may be the peak values of the current in Equations (9) and (10).

In some instances, circuit 1316 may also add a transistor (not shown) that may offset the current to determine an average current. Offsetting the current may be beneficial when the current waveform passes through zero and some of the current is negative, which can lead to the average current being zero. The offset may help generate an average current when the current is negative.

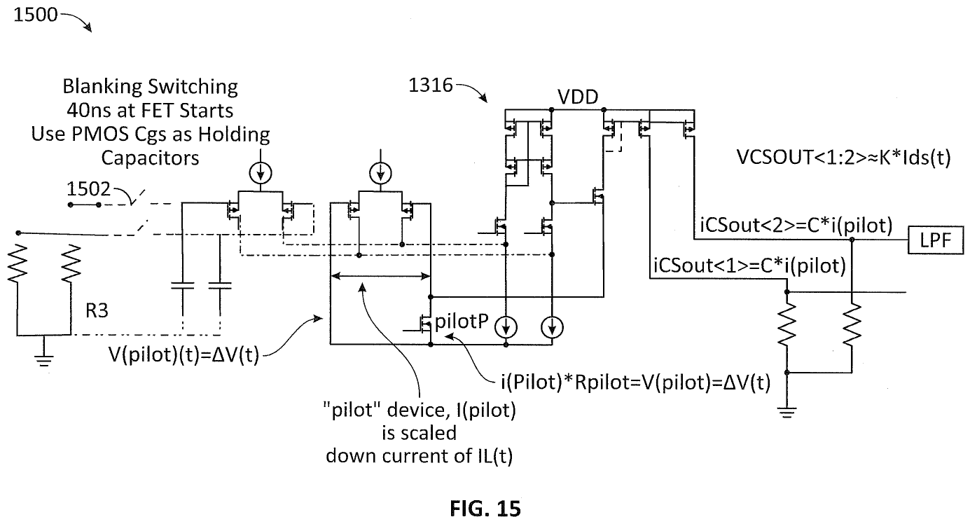

In some instances, circuit 1316 also includes blanking circuitry. FIG. 15 is a circuit diagram of a portion of circuit 1316 that includes blanking circuitry, according to some embodiments. Blanking circuitry 1502 may include switches that disable the current from flowing from mirror circuitry 1308A-B to circuit 1316. This can occur, in some embodiments, when S5 switch circuit 1302 and S6 switch circuit 1304 switch from the on to off state and vice versa, which may cause a spike in switch current. The blanking circuitry 1502 may open switches which prevent the current from flowing, and thus avoid or reducing the likelihood of measuring the spike as the peak current or including the spike in the measurements of the average current.

In some embodiments, FIGS. 13A and 13B may include nulling circuitry 1330A and 1330B. Nulling circuitry 1330A ensures that when S5 switch circuit 1302 is off, current from S5 switch circuit 1302 does not flow to the mirror circuitry 1308A. Similarly, nulling circuitry 1330B ensures that when S6 switch circuit 1304 is off, current from S6 switch circuit 1304 does not flow to the mirror circuitry 1308B. Nulling circuitry 1330A ensures that mirror circuitry 1308A-B receives current either from S5 switch circuit 1302 or from S6 switch circuit 1304, but not both.

As discussed above, mirror circuitry 1308A operates at a high voltage. In some embodiments, FIG. 13A includes protection devices 1332. Protection devices 1332 may protect the circuitry in box 1334, including control circuitry in mirror circuitry 1308A from the high input voltage (V_{IN}), by clamping the voltage. Protection devices 1332 may also protect circuitry in box 1336, which includes devices operating in a low voltage domain. Protection devices 1332 may be PMOS clamps.

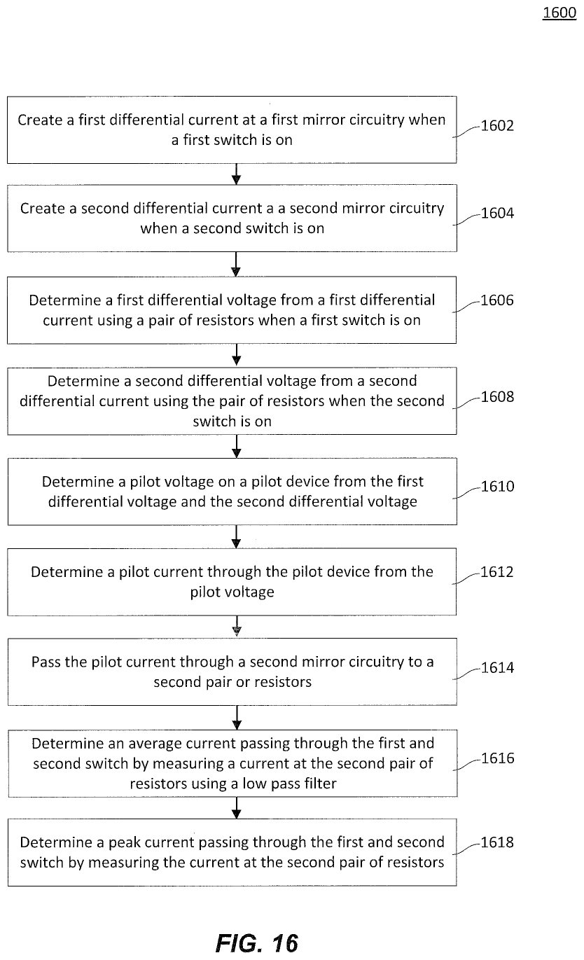

FIG. 16 is an example method 1600 for measuring an average current and a peak current of a multi-level converter, in accordance with one or more embodiments. Method 1600 may be implemented using components and circuits discussed in FIGS. 1-15.

At operation 1602, a first differential current is created when S5 switch circuit is on. For example, mirror circuitry 1308A may create a differential current 1310A. Differential current 1310A may be equal to the voltage across S5 switch circuit 1302 divided by a ratio of an internal resister R1 1312 in mirror circuitry 1308A and K1.

At operation 1604, a second differential current is created when S6 switch circuit is on. For example, mirror circuitry 1308B may create a differential current 1310B. Differential current 1310B may be equal to the voltage across S6 switch circuit 1304 divided by a ratio of an internal resister R2 1313 in mirror circuitry 1308B and K3.

At operation 1606, a first differential voltage from the differential current is determined when S5 switch circuit is on. For example, a first differential voltage is determined by passing the differential current 1310A through a pair of resistors R3 1314A-B.

At operation 1608, a second differential voltage from the differential current is determined when S6 switch circuit is on. For example, a second differential voltage is created by passing the differential current 1310B through a pair of resistors R3 1314A-B.

At operation 1610, a voltage across a pilot device is created. For example, differential pair inputs 1318A and 1318B in circuit 1316 may create a voltage across the pilot device 1320 that is the same as the first differential voltage and the second differential voltage across the pair of resistors R3 1314A-B.

At operation 1612, a current through the pilot device is determined. For example, a current through pilot device 1320 is determined from the voltage across the pilot device 1320.

At operation 1614, a current is passed through a second mirror circuit to a pair of resistors. For example, the pilot current may pass through a second mirror circuit 1322 to a pair of resistors 1324A-B.

At operation 1616, an average current is determined by passing the current in operation 1514 through the LPF 1326.

At operation 1618, a peak current is determined by measuring a current at resistors 1324A-B.

Further aspects of the present disclosure include the following:

Aspect 1 includes a system comprising: a first circuitry configured to create a first differential current based on a first voltage across a first switch of a power converter when the first switch is in an on state; a second circuitry configured to create a second differential current based on a second voltage across a second switch of the power converter when the second switch is in the on state; a first pair of resistors configured to create a first differential voltage from the first differential current and a second differential voltage from the second differential current; a pilot device configured to: generate a pilot voltage based on the first differential voltage and the second differential voltage; and generate a pilot current from the pilot voltage; a third circuitry configured to pass the pilot current to a second pair of resistors; and a low pass filter configured to measure a current at the second pair of resistors and generate an average current of the power converter.

Aspect 2 includes the system of aspect 1, wherein the first switch and the second switch form a pair of switches that alternate between being in the on state and the off state.

Aspect 3 includes the system of any of aspects 1-2, wherein the power converter is a multi-level power converter and the pair of switches are a first switch and a last switch in a configuration of the multi-level power converter.

Aspect 4 includes the system of any of aspects 1-3, further comprising: clamping devices configured to clamp voltage in the first circuitry.

Aspect 5 includes the system of any of aspects 1-4, further comprising: a nulling circuitry in the first circuitry configured to prevent a current flow to the first circuitry when the first switch is off.

Aspect 6 includes the system of any of aspects 1-5, further comprising: a blanking circuitry configured to prevent a current flow from the first circuitry or the second circuitry to the pilot device when the first switch transitions from the on state to the off state or when the second switch transitions from the on state to the off state.

Aspect 7 includes the system of any of aspects 1-6, further comprising a current control loop in a controller configured to receive the average current.

Aspect 8 includes a system comprising: a first mirror circuitry configured to create a first differential current based on a first voltage across a first switch of a power converter when the first switch is in an on state; a second mirror circuitry configured to create a second differential current based on a second voltage across a second switch of the power converter when the second switch is in the on state; a first pair of resistors configured to create a first differential voltage from the first differential current and a second differential voltage from the second differential current; a pilot device configured to generate a pilot current based on the first differential voltage and the second differential voltage; a third circuitry configured to pass the pilot current to a second pair of resistors; and determine a peak current at the second pair of resistors.

Aspect 9 includes the system of aspect 8, wherein the first switch and the second switch form a pair of switches that alternate between being on and off.

Aspect 10 includes the system of any of aspects 8-9, wherein the power converter is a multi-level power converter and the pair of switches are outer switches from multiple switches in the multi-level power converter.

Aspect 11 includes the system of any of aspects 8-10, wherein the pilot device is further configured to generate a pilot voltage from the first differential voltage and the second differential voltage, and the pilot current from the pilot voltage.

Aspect 12 includes the system of any of aspects 8-11, further comprising: a nulling circuitry in the first circuitry configured to prevent a current flowing to the first circuitry when the first switch is off.

Aspect 13 includes the system of any of aspects 8-12, further comprising: a blanking circuitry configured to prevent a current flow from the first circuitry or the second circuitry to the pilot device when the first switch transitions from the on state to the off state or when the second switch transitions from the on state to the off state.

Aspect 14 includes the system of any of aspects 8-13, further comprising a controller configured to receive the peak current to set a duty cycle for the power converter.

Aspect 15 includes a method comprising: generating, at a first mirror circuitry, a first differential current based on a first voltage across a first switch of a power converter when the first switch is on; generating, at a second mirror circuitry, a second differential current based on a second voltage across a second switch of the power converter when the second switch is on; generating a first differential voltage from the first differential current and a second differential voltage from the second differential current; converting, at a pilot device, the first differential voltage and the second differential voltage into a pilot current; passing the pilot current through a third circuitry to a pair of resistors; and measuring an average current of the power converter at the pair of resistors.

Aspect 16 includes the method of aspect 15, wherein measuring the average current further comprises passing a current at the pair of resistors to a low pass filter.

Aspect 17 includes the method of any of aspects 15-16, further comprising: measuring a peak current at the pair of resistors.

Aspect 18 includes the method of any of aspects 15-17, wherein the power converter is a multi-level power converter and the pair of switches are a first switch and a last switch in a plurality of sequential switches in the multi-level power converter that alternate between being on and off.

Aspect 19 includes the method of any of aspects 15-18, wherein the first differential voltage and the second differential voltage are generated at a second pair of resisters.

Aspect 20 includes the method of any of aspects 15-19, wherein converting the first differential voltage and the second differential voltage into a pilot current further comprises: generating a pilot voltage that is the same as the first differential voltage and the second differential voltage; and generating the pilot current from the pilot voltage.

### General Benefits and Advantages of Multi-Level Power Converters

Embodiments of the current invention improve the power density and/or power efficiency of incorporating circuits and circuit modules or blocks. As a person of ordinary skill in the art should understand, a system architecture is beneficially impacted utilizing embodiments of the current invention in critical ways, including lower power and/or longer battery life. The current invention therefore specifically encompasses system-level embodiments that are creatively enabled by inclusion in a large system design and application.

More particularly, multi-level power converters provide or enable numerous benefits and advantages, including:
adaptability to applications in which input and/or output voltages may have a wide dynamic-range (e.g., varying battery input voltage levels, varying output voltages);
efficiency improvements on the run-time of devices operating on portable electrical energy sources (batteries, generators or fuel cells using liquid or gaseous fuels, solar cells, etc.);
efficiency improvements where efficiency is important for thermal management, particularly to protect other components (e.g., displays, nearby ICs) from excessive heat;
enabling design optimizations for power efficiency, power density, and form-factor of the power converter—for example, smaller-size multi-level power converters may allow placing power converters in close proximity to loads, thus increasing efficiency, and/or to lower an overall bill of materials;
the ability to take advantage of the performance of smaller, low voltage transistors;
adaptability to applications in which power sources can vary widely, such as batteries, other power converters, generators or fuel cells using liquid or gaseous fuels, solar cells, line voltage (AC), and DC voltage sources (e.g., USB, USB-C, power-over Ethernet, etc.);
adaptability to applications in which loads may vary widely, such as ICs in general (including microprocessors and memory ICs), electrical motors and actuators, transducers, sensors, and displays (e.g., LCDs and LEDs of all types);
the ability to be implemented in a number of IC technologies (e.g., MOSFETs, GaN, GaAs, and bulk silicon) and packaging technologies (e.g., flip chips, ball-grid arrays, wafer level scale chip packages, wide-fan out packaging, and embedded packaging).

The advantages and benefits of multi-level power converters enable usage in a wide array of applications. For example, applications of multi-level power converters include portable and mobile computing and/or communication products and components (e.g., notebook computers, ultra-book computers, tablet devices, and cell phones), displays (e.g., LCDs, LEDs), radio-based devices and systems (e.g., cellular systems, WiFi, Bluetooth, Zigbee, Z-Wave, and GPS-based devices), wired network devices and systems, data centers (e.g., for battery-backup systems and/or power conversion for processing systems and/or electronic/optical networking systems), internet-of-things (IOT) devices (e.g., smart switches and lights, safety sensors, and security cameras), household appliances and electronics (e.g., set-top boxes, battery-operated vacuum cleaners, appliances with built-in radio transceivers such as washers, dryers, and refrigerators), AC/DC power converters, electric vehicles of all types (e.g., for drive trains, control systems, and/or infotainment systems), and other devices and systems that utilize portable electricity generating sources and/or require power conversion.

Radio system usage includes wireless RF systems (including base stations, relay stations, and hand-held transceivers) that use various technologies and protocols, including various types of orthogonal frequency-division multiplexing (“OFDM”), quadrature amplitude modulation (“QAM”), Code-Division Multiple Access (“CDMA”), Time-Division Multiple Access (“TDMA”), Wide Band Code Division Multiple Access (“W-CDMA”), Global System for Mobile Communications (“GSM”), Long Term Evolution (“LTE”), 5G, and WiFi (e.g., 802.11a, b, g, ac, ax), as well as other radio communication standards and protocols.

### Programmable Embodiments

Some or all aspects of the invention, particularly the Multi-Level Switch State Selector 1014 of FIG. 10, may be implemented in hardware or software, or a combination of both (e.g., programmable logic arrays). Unless otherwise specified, the algorithms included as part of the invention are not inherently related to any particular computer or other apparatus. In particular, various general purpose computing machines may be used with programs written in accordance with the teachings herein, or it may be more convenient to use a special purpose computer or special-purpose hardware (such as integrated circuits) to perform particular functions. Thus, embodiments of the invention may be implemented in one or more computer programs (i.e., a set of instructions or codes) executing on one or more programmed or programmable computer systems (which may be of various architectures, such as distributed, client/server, or grid) each comprising at least one processor, at least one data storage system (which may include volatile and non-volatile memory and/or storage elements), at least one input device or port, and at least one output device or port. Program instructions or code may be applied to input data to perform the functions described in this disclosure and generate output information. The output information may be applied to one or more output devices in known fashion.

Each such computer program may be implemented in any desired computer language (including machine, assembly, or high-level procedural, logical, or object-oriented programming languages) to communicate with a computer system, and may be implemented in a distributed manner in which different parts of the computation specified by the software are performed by different computers or processors. In any case, the computer language may be a compiled or interpreted language. Computer programs implementing some or all of the invention may form one or more modules of a larger program or system of programs. Some or all of the elements of the computer program can be implemented as data structures stored in a computer readable medium or other organized data conforming to a data model stored in a data repository.

Each such computer program may be stored on or downloaded to (for example, by being encoded in a propagated signal and delivered over a communication medium such as a network) a tangible, non-transitory storage media or device (e.g., solid state memory media or devices, or magnetic or optical media) for a period of time (e.g., the time between refresh periods of a dynamic memory device, such as a dynamic RAM, or semi-permanently or permanently), the storage media or device being readable by a general or special purpose programmable computer or processor for configuring and operating the computer or processor when the storage media or device is read by the computer or processor to perform the procedures described above. The inventive system may also be considered to be implemented as a non-transitory computer-readable storage medium, configured with a computer program, where the storage medium so configured causes a computer or processor to operate in a specific or predefined manner to perform the functions described in this disclosure.

### FABRICATION TECHNOLOGIES & OPTIONS

In various embodiments of multi-level power converters, it may be beneficial to use specific types of capacitors, particularly for the fly capacitors. For example, it is generally useful for such capacitors to have low equivalent series resistance (ESR), low DC bias degradation, high capacitance, and small volume. Low ESR is especially important for multi-level power converters that incorporate additional switches and fly capacitors to increase the number of voltage levels. Selection of a particular capacitor should be made after consideration of specifications for power level, efficiency, size, etc. Various types of capacitor technologies may be used, including ceramic (including multi-layer ceramic capacitors), electrolytic capacitors, film capacitors (including power film capacitors), and IC-based capacitors. Capacitor dielectrics may vary as needed for particular applications, and may include dielectrics that are paraelectric, such as silicon dioxide (SiO₂), hafnium dioxide (HFO₂), or aluminum oxide Al₂O₃. In addition, multi-level power converter designs may beneficially utilize intrinsic parasitic capacitances (e.g., intrinsic to the power FETs) in conjunction with or in lieu of designed capacitors to reduce circuit size and/or increase circuit performance. Selection of capacitors for multi-level power converters may also take into account such factors as capacitor component variations, reduced effective capacitance with DC bias, and ceramic capacitor temperature coefficients (minimum and maximum temperature operating limits, and capacitance variation with temperature).

Similarly, in various embodiments of multi-level power converters, it may be beneficial to use specific types of inductors. For example, it is generally useful for the inductors to have low DC equivalent resistance, high inductance, and small volume.

The controller(s) used to control startup and operation of a multi-level power converter may be implemented as a microprocessor, a microcontroller, a digital signal processor (DSP), register-transfer level (RTL) circuitry, and/or combinatorial logic.

The term “MOSFET”, as used in this disclosure, includes any field effect transistor (FET) having an insulated gate whose voltage determines the conductivity of the transistor, and encompasses insulated gates having a metal or metal-like, insulator, and/or semiconductor structure. The terms “metal” or “metal-like” include at least one electrically conductive material (such as aluminum, copper, or other metal, or highly doped polysilicon, graphene, or other electrical conductor), “insulator” includes at least one insulating material (such as silicon oxide or other dielectric material), and “semiconductor” includes at least one semiconductor material.

As used in this disclosure, the term “radio frequency” (RF) refers to a rate of oscillation in the range of about 3 kHz to about 300 GHz. This term also includes the frequencies used in wireless communication systems. An RF frequency may be the frequency of an electromagnetic wave or of an alternating voltage or current in a circuit.

With respect to the figures referenced in this disclosure, the dimensions for the various elements are not to scale; some dimensions have been greatly exaggerated vertically and/or horizontally for clarity or emphasis. In addition, references to orientations and directions (e.g., “top”, “bottom”, “above”, “below”, “lateral”, “vertical”, “horizontal”, etc.) are relative to the example drawings, and not necessarily absolute orientations or directions.

Various embodiments of the invention can be implemented to meet a wide variety of specifications. Unless otherwise noted above, selection of suitable component values is a matter of design choice. Various embodiments of the invention may be implemented in any suitable integrated circuit (IC) technology (including but not limited to MOSFET structures), or in hybrid or discrete circuit forms. Integrated circuit embodiments may be fabricated using any suitable substrates and processes, including but not limited to standard bulk silicon, high-resistivity bulk CMOS, silicon-on-insulator (SOI), and silicon-on-sapphire (SOS). Unless otherwise noted above, embodiments of the invention may be implemented in other transistor technologies such as bipolar, BiCMOS, LDMOS, BCD, GaAs HBT, GaN HEMT, GaAs pHEMT, and MESFET technologies. However, embodiments of the invention are particularly useful when fabricated using an SOI or SOS based process, or when fabricated with processes having similar characteristics. Fabrication in CMOS using SOI or SOS processes enables circuits with low power consumption, the ability to withstand high power signals during operation due to FET stacking, good linearity, and high frequency operation (i.e., radio frequencies up to and exceeding 300 GHz). Monolithic IC implementation is particularly useful since parasitic capacitances generally can be kept low (or at a minimum, kept uniform across all units, permitting them to be compensated) by careful design.

Voltage levels may be adjusted, and/or voltage and/or logic signal polarities reversed, depending on a particular specification and/or implementing technology (e.g., NMOS, PMOS, or CMOS, and enhancement mode or depletion mode transistor devices). Component voltage, current, and power handling capabilities may be adapted as needed, for example, by adjusting device sizes, serially “stacking” components (particularly FETs) to withstand greater voltages, and/or using multiple components in parallel to handle greater currents. Additional circuit components may be added to enhance the capabilities of the disclosed circuits and/or to provide additional functionality without significantly altering the functionality of the disclosed circuits.

Circuits and devices in accordance with the present invention may be used alone or in combination with other components, circuits, and devices. Embodiments of the present invention may be fabricated as integrated circuits (ICs), which may be encased in IC packages and/or in modules for ease of handling, manufacture, and/or improved performance. In particular, IC embodiments of this invention are often used in modules in which one or more of such ICs are combined with other circuit blocks (e.g., filters, amplifiers, passive components, and possibly additional ICs) into one package. The ICs and/or modules are then typically combined with other components, often on a printed circuit board, to form part of an end product such as a cellular telephone, laptop computer, or electronic tablet, or to form a higher-level module which may be used in a wide variety of products, such as vehicles, test equipment, medical devices, etc. Through various configurations of modules and assemblies, such ICs typically enable a mode of communication, often wireless communication.

A number of embodiments of the disclosure have been described. It is to be understood that various modifications may be made without departing from the spirit and scope of the disclosure. For example, some of the steps described above may be order independent, and thus can be performed in an order different from that described. Further, some of the steps described above may be optional. Various activities described with respect to the methods identified above can be executed in repetitive, serial, and/or parallel fashion.

It is to be understood that the foregoing description is intended to illustrate and not to limit the scope of the disclosure, which is defined by the scope of the following claims, and that other embodiments are within the scope of the claims. In particular, the scope of the disclosure includes any and all feasible combinations of one or more of the processes, machines, manufactures, or compositions of matter set forth in the claims below. (Note that the parenthetical labels for claim elements are for ease of referring to such elements, and do not in themselves indicate a particular required ordering or enumeration of elements; further, such labels may be reused in dependent claims as references to additional elements without being regarded as starting a conflicting labeling sequence).

What is claimed is:

1. A system comprising:
a first circuitry configured to create a first differential current based on a first voltage across a first switch of a power converter when the first switch is in an on state;
a second circuitry configured to create a second differential current based on a second voltage across a second switch of the power converter when the second switch is in the on state;
a first pair of resistors configured to create a first differential voltage from the first differential current and a second differential voltage from the second differential current;
a pilot device configured to:
generate a pilot voltage based on the first differential voltage and the second differential voltage; and
generate a pilot current from the pilot voltage;
a third circuitry configured to pass the pilot current to a second pair of resistors; and
a low pass filter configured to measure a current at the second pair of resistors and generate an average current of the power converter.

2. The system of claim 1, wherein the first switch and the second switch form a pair of switches that alternate between being in the on state and the off state.

3. The system of claim 2, wherein the power converter is a multi-level power converter and the pair of switches are a first switch and a last switch in a configuration of the multi-level power converter.

4. The system of claim 1, further comprising:
clamping devices configured to clamp voltage in the first circuitry.

5. The system of claim 1, further comprising:
a nulling circuitry in the first circuitry configured to prevent a current flow to the first circuitry when the first switch is off.

6. The system of claim 1, further comprising:
a blanking circuitry configured to prevent a current flow from the first circuitry or the second circuitry to the pilot device when the first switch transitions from the on state to the off state or when the second switch transitions from the on state to the off state.

7. The system of claim 1, further comprising a current control loop in a controller configured to receive the average current.

8. A system comprising:
a first mirror circuitry configured to create a first differential current based on a first voltage across a first switch of a power converter when the first switch is in an on state;
a second mirror circuitry configured to create a second differential current based on a second voltage across a second switch of the power converter when the second switch is in the on state;
a first pair of resistors configured to create a first differential voltage from the first differential current and a second differential voltage from the second differential current;
a pilot device configured to generate a pilot current based on the first differential voltage and the second differential voltage;
a third circuitry configured to pass the pilot current to a second pair of resistors; and
determine a peak current at the second pair of resistors.

9. The system of claim 8, wherein the first switch and the second switch form a pair of switches that alternate between being on and off.

10. The system of claim 8, wherein the power converter is a multi-level power converter and the pair of switches are outer switches from multiple switches in the multi-level power converter.

11. The system of claim 8, wherein the pilot device is further configured to generate a pilot voltage from the first differential voltage and the second differential voltage, and the pilot current from the pilot voltage.

12. The system of claim 8, further comprising:
a nulling circuitry in the first circuitry configured to prevent a current flowing to the first circuitry when the first switch is off.

13. The system of claim 8, further comprising:
a blanking circuitry configured to prevent a current flow from the first circuitry or the second circuitry to the pilot device when the first switch transitions from the on state to the off state or when the second switch transitions from the on state to the off state.

14. The system of claim 8, further comprising a controller configured to receive the peak current to set a duty cycle for the power converter.

15. A method comprising:
generating, at a first mirror circuitry, a first differential current based on a first voltage across a first switch of a power converter when the first switch is on;
generating, at a second mirror circuitry, a second differential current based on a second voltage across a second switch of the power converter when the second switch is on;
generating a first differential voltage from the first differential current and a second differential voltage from the second differential current;
converting, at a pilot device, the first differential voltage and the second differential voltage into a pilot current;
passing the pilot current through a third circuitry to a pair of resistors; and
measuring an average current of the power converter at the pair of resistors.

16. The method of claim 15, wherein measuring the average current further comprises passing a current at the pair of resistors to a low pass filter.

17. The method of claim 15, further comprising:
measuring a peak current at the pair of resistors.

18. The method of claim 15, wherein the power converter is a multi-level power converter and the pair of switches are a first switch and a last switch in a plurality of sequential switches in the multi-level power converter that alternate between being on and off.

19. The method of claim 15, wherein the first differential voltage and the second differential voltage are generated at a second pair of resisters.

20. The method of claim 15, wherein converting the first differential voltage and the second differential voltage into a pilot current further comprises:
generating a pilot voltage that is the same as the first differential voltage and the second differential voltage; and
generating the pilot current from the pilot voltage.
